(19) United States
(12) Patent Application Publication
(10) Pub. No.: US 2011/0288807 A1
(43) Pub. Date: Nov. 24, 2011

(54) FAILURE DETECTING METHOD, SEMICONDUCTOR DEVICE, AND MICROCOMPUTER APPLICATION SYSTEM

(75) Inventors: Takashi Iwase, Kanagawa (JP); Masamichi Fujito, Kanagawa (JP)

(73) Assignee: RENESAS ELECTRONICS CORPORATION

(21) Appl. No.: 13/111,942

(22) Filed: May 19, 2011

(30) Foreign Application Priority Data
May 20, 2010 (JP) 2010-116467

(51) Int. Cl. G06F 19/00; G01R 31/00

(52) U.S. Cl. 702/117; 324/750.02

(57) ABSTRACT

The present invention is directed to improve the precision of failure detection by performing the failure detection by changing an analog amount of a circuit to be subjected to the failure detection. An analog amount of the circuit to be subjected to failure detection is changed under a predetermined condition by a tuning circuit, and a state change in the circuit to be subjected to failure detection based on the change in the analog amount in the circuit to be subjected to failure detection is determined by a failure detection circuit, thereby detecting a failure in the circuit to be subjected to failure detection. In such a manner, without monitoring an output of the failure detection circuit on the outside of a semiconductor device, a failure in the circuit to be subjected to failure detection can be detected. Moreover, an actual state change in the circuit to be subjected to failure detection based on a change in the analog amount in the circuit to be subjected to failure detection is determined by the failure detection circuit, so that precision of failure detection is improved.

### CROSS-REFERENCE TO RELATED APPLICATIONS

The disclosure of Japanese Patent Application No. 2010-116467 filed on May 20, 2010 including the specification, drawings and abstract is incorporated herein by reference in its entirety.

### BACKGROUND

The present invention relates to a failure detecting technique and, for example, to a technique effectively applied to a microcomputer and a microcomputer application system.

Patent document 1 discloses a technique for independently determining only whether a read system is good or not at the time of conducting a functional test of a memory device. In the technique, the potential of a bit line or current driving capability can be forcedly controlled from the outside. In addition, the potential of the bit line and current drive capability can be sensed from the outside to detect a failure related to a read system circuit such as disconnection, short-circuit, or the like of the bit line on the basis of a control state from the outside and an output of a sense amplifier.

Patent document 2 discloses a technique for reading data from a memory cell with high precision even by making the start timing of a sense amplifier circuit retarded in a nonvolatile semiconductor storage device of a dynamic sense type using a differential sense amplifier circuit. In the technique, a memory cell 1 is coupled to a bit line BL0 by a word line WL, a reference memory cell 2 is coupled to another bit line BL1 by a reference word line RWL, and the potential difference between the bit lines BL0 and BL1 is sensed by a sense amplifier SA. At the time of reading data of the memory cell 1, both of the bit lines BL0 and BL1 are precharged to a predetermined potential by a precharge circuit 4 at the beginning of the data reading. After the precharging, currents of the same amount are supplied to the bit lines BL0 and BL1 by a bit line current supplying circuit 3.

### DOCUMENTS OF RELATED TECHNIQUES

### Patent Documents

### [Patent Document 1]

Japanese Unexamined Patent Application Publication No. H05-74198

### [Patent Document 2]

Japanese Unexamined Patent Application Publication No. 2003-242793

### SUMMARY

The inventors of the present invention have examined detection of a failure in an analog circuit provided in a microcomputer as an example of a semiconductor device. Whether an analog circuit provided in a microcomputer operates normally or not can be recognized by monitoring voltage applied to the analog circuit, current flowing in the analog circuit, timings of main signals in the analog circuit, or the like on the outside of the microcomputer.

On the other hand, it is difficult to detect, from the outside, a failure in each of hundreds of devices in a module such as MOS transistors for reference provided on the input side of a sense amplifier in a semiconductor memory. For such devices, an indirect failure determination by comparing data read from a memory cell with an expectation value is performed. In such a failure determination, however, the present invention found out the possibility that even when the performance of a device to be subjected to failure detection is not fully displayed, when data read from a memory cell coincides with an expectation value, it is erroneously determined that the analog circuit operates normally.

Such an issue is not considered in the patent documents 1 and 2.

An object of the present invention is to provide a technique for improving failure detection precision by performing failure detection by changing an analog amount of a circuit as an object of the failure detection.

The above and other objects and novel features of the present invention will become apparent from the description of the specification and the appended drawings.

A representative one of inventions disclosed in the present application will be briefly described as follows.

The present invention is directed to detect a failure in a circuit to be subjected to failure detection by changing an analog amount of the circuit to be subjected to failure detection under a predetermined condition by a tuning circuit and determining a state change of the circuit to be subjected to failure detection based on a change in the analog amount of the circuit to be subjected to failure detection by a failure detection circuit.

An effect obtained by the representative one of the inventions disclosed in the present application will be briefly described as follows.

That is, by performing the failure detection by changing an analog amount of a circuit as an object of failure detection, the precision of the failure detection can be improved.

### BRIEF DESCRIPTION OF THE DRAWINGS

FIG. 1 is a block diagram showing a configuration example of a microcomputer as an example of a semiconductor device according to the present invention.

FIG. 2 is a block diagram showing another configuration example of a microcomputer as an example of a semiconductor device according to the present invention.

FIG. 3 is a block diagram showing another configuration example of a microcomputer as an example of the semiconductor device according to the present invention.

FIG. 4 is a block diagram showing a configuration example of a memory module mounted on the microcomputer illustrated in FIG. 3.

FIG. 5 is a diagram for explaining a configuration example of a memory mat part included in the memory module shown in FIG. 4.

FIG. 6 is a circuit diagram of a configuration example of a circuit to be compared with a circuit illustrated in FIG. 8.

FIGS. 7A and 7B are diagrams for explaining operation of a main part in the circuit shown in FIG. 6.

FIG. 8 is a circuit diagram showing a configuration example of a peripheral part of a hierarchical sense amplifier circuit illustrated in FIG. 4.

FIGS. 9A to 9E are diagrams for explaining operation of detecting a failure in the main part in the configuration shown in FIG. 8.

FIG. 10 is a flowchart for detecting a failure in the main part in the configuration shown in FIG. 8.

FIG. 11 is a diagram for explaining a failure detection in an n-channel type MOS transistor for reference shown in FIG. 8.

FIG. 12 is a circuit diagram showing another configuration example of a main part in the memory module illustrated in FIG. 4.

FIG. 13 is an explanatory diagram showing main operations of the configuration illustrated in FIG. 12 and states of signals.

FIG. 14 is a circuit diagram of a configuration example of a verify sense amplifier in the memory module shown in FIG. 4.

FIG. 15 is a flowchart of detecting a failure in a p-channel-type MOS transistor for reference in FIG. 14.

FIG. 16 is a circuit diagram of a configuration example of a power supply circuit included in the memory module shown in FIG. 4.

FIG. 17 is a flowchart of detecting a failure in a power supply circuit shown in FIG. 16.

FIG. 18 is a circuit diagram of a configuration example of the hierarchical sense amplifier circuit and its periphery shown in FIG. 4.

FIG. 19 is a circuit diagram of a configuration example of a delay circuit in FIG. 18.

FIG. 20 is a block diagram of a configuration example of a clock generator in FIG. 3.

FIG. 21 is a flowchart of determining consistency among a plurality of oscillators in FIG. 20.

FIG. 22 is an explanatory diagram of a microcomputer application system.

FIG. 23 is another explanatory diagram of the microcomputer application system.

### DETAILED DESCRIPTION

### 1. Outline of Embodiments

First, outline of representative embodiments of the invention disclosed in the application will be described. Reference numerals in the diagram which will be referred to in parentheses in the explanation of the outline of the representative embodiments just denote devices included in the concept of the components.

[1] A failure detecting method according to a representative embodiment of the present invention includes the steps of: changing an analog amount of the circuit (104B) to be subjected to failure detection under a predetermined condition by a tuning circuit (104A); and determining a state change of the circuit to be subjected to failure detection on the basis of the change in the analog amount in the circuit to be subjected to failure detection by a failure detection circuit (103), thereby detecting a failure in the circuit to be subjected to failure detection.

With the configuration, a state change in the circuit to be subjected to failure detection based on a change in the analog amount in the circuit to be subjected to failure detection is determined by a failure detection circuit, thereby detecting a failure in the circuit to be subjected to failure detection. Consequently, a failure in the circuit to be subjected to failure detection can be detected without monitoring an output of the failure detection circuit (103) on the outside of the semiconductor device. Moreover, since an actual state change in the circuit to be subjected to failure detection based on a change in the analog amount in the circuit to be subjected to failure detection is determined by the failure detection circuit, precision of failure detection can be improved.

[2] In the method [1], operations of the tuning circuit and the circuit to be subjected to failure detection can be sequentially controlled by a sequencer under control of a central processing unit. In such a manner, the load on the central processing unit can be reduced.

[3] A semiconductor device (10) according to a representative embodiment of the present invention includes a central processing unit (102). The semiconductor device is provided with: a circuit (104B) to be subjected to failure detection, as an object of failure detection; a tuning circuit (104A) for changing an analog amount of the circuit to be subjected to failure detection under control of the central processing unit; and a failure detection circuit (103) for detecting a failure in the circuit to be subjected to failure detection by determining a state change of the circuit to be subjected to failure detection based on a change in an analog amount in the circuit to be subjected to failure detection under control of the central processing unit.

With the configuration, a state change in the circuit to be subjected to failure detection based on a change in the analog amount in the circuit to be subjected to failure detection is determined by a failure detection circuit, thereby detecting a failure in the circuit to be subjected to failure detection. Consequently, a failure in the circuit to be subjected to failure detection can be detected without monitoring an output of the failure detection circuit (103) on the outside of the semiconductor device. Moreover, since an actual state change in the circuit to be subjected to failure detection based on a change in the analog amount in the circuit to be subjected to failure detection is determined by the failure detection circuit, precision of failure detection can be improved.

[4] The semiconductor device [3] can be further provided with a sequencer (105) for sequentially controlling operations of the tuning circuit and the circuit to be subjected to failure detection under control of the central processing unit. With the configuration, the load on the central processing unit can be reduced.

[5] In the semiconductor device [4], the circuit to be subjected to failure detection includes a first transistor (Mref1) for receiving current from a first bit line for reading data in a flash memory which can be accessed by the central processing unit, and a second transistor (Mref2) for receiving current from a second bit line for reference corresponding to the first bit line. The tuning circuit includes a first reference voltage generating circuit (602) capable of changing current flowing in the first transistor separately from the second transistor, and a second reference voltage generating circuit (603) capable of changing current flowing in the second transistor separately from the first transistor. The failure detection circuit makes a failure determination on the first and second transistors on the basis of an output of a sense amplifier that determines a potential difference between the first and second bit lines. It can consequently improve the precision of determination of a failure in the first and second transistors on the basis of an output of the sense amplifier that determines a potential difference between the first and second bit lines.

[6] In the semiconductor device [4], the circuit to be subjected to failure detection includes a first circuit (Mref1, Mref 2) for generating determination current of a first sense amplifier for data reading in a flash memory which can be accessed by the central processing unit, and a second circuit (M58) for generating determination current of a second sense amplifier for verification in the flash memory. The tuning circuit includes a third circuit (1203, 1202) for changing the relation between the determination current of the first sense amplifier and the determination current of the second sense amplifier under a predetermined condition. The failure detection circuit performs failure determination on the first and second circuits by determining consistency between the determination currents in the first and second sense amplifiers on the basis of an output of the first sense amplifier or an output of the second sense amplifier. It can improve the precision of the failure determination on the first and second circuits.

[7] In the semiconductor device [4], the circuit to be subjected to failure detection includes a reference transistor (Mref3) for passing reference current to an input-side circuit of a verify sense amplifier in a flash memory which can be accessed by the central processing unit. The tuning circuit includes a bias voltage generating circuit (1402) capable of changing current flowing in the reference transistor. The failure detection circuit performs failure detection on the reference transistor (Mref3) on the basis of an output of the verify sense amplifier. It can improve the precision of the failure determination on the reference transistor (Mref3).

[8] In the semiconductor device [4], the circuit to be subjected to failure detection includes a first analog unit (1602) for forming power source voltages for operating the components. The tuning circuit includes a first tuning circuit (1605) capable of changing an output voltage of the first power supply circuit. The failure detection circuit includes a second analog unit (1612) equivalent to the first power supply circuit, a second tuning circuit (1607) capable of changing output voltage of the second analog unit, and a comparator (CMP1) for comparing the output voltage of the first analog unit and the output voltage of the second analog unit. The failure detection circuit performs failure detection on the first analog unit on the basis of an output of the comparator in the case where the output voltage of the first analog unit or the output voltage of the second analog unit is changed by the first tuning circuit or the second tuning circuit. It can improve the precision of the failure determination on the first analog unit.

[9] In the semiconductor device [4], the circuit to be subjected to failure detection includes a first delay circuit (DLY1) and a second delay circuit (DLY2) for forming a signal for starting a sense amplifier by delaying a clock signal. The tuning circuit includes a first tuning circuit (1802) capable of changing delay time in the first delay circuit and a second tuning circuit (1803) capable of changing delay time in the second delay circuit separately from the first circuit. The failure detection circuit performs a failure determination on the first and second delay circuits by comparing an output value of the sense amplifier in the case where the delay time in the first delay circuit is changed by the first tuning circuit and an output value of the sense amplifier in the case where the delay time in the second delay circuit is changed by the second tuning circuit. It can improve the precision of the failure determination on the first and second delay circuits.

[10] In the semiconductor device [4], the circuit to be subjected to failure detection includes a first oscillator (2001) which can oscillate at a predetermined frequency and a second oscillator (2002) which can oscillate at a predetermined frequency. The tuning circuit includes a first periodic tuning circuit (2005) capable of tuning an oscillation period in the first oscillator and a second periodic tuning circuit (2006) capable of tuning an oscillation period in the second oscillator separately from the first oscillator. The failure detection circuit performs a failure determination on the first and second oscillators by comparing an output of the first oscillator in the case where the oscillation period in the first oscillator is changed by the first tuning circuit and an output of the second oscillator in the case where the oscillation period in the second oscillator is changed by the second tuning circuit. It can improve the precision of the failure detection on the first and second oscillators.

[11] A microcomputer application system in which a microcomputer executing a predetermined control program is mounted can be configured. In this case, the semiconductor device of any one of [3] to [10] can be applied as the microcomputer. The semiconductor device performs failure detection by changing an analog amount of a circuit as an object of failure detection, thereby improving the precision of the failure detection. Thus, the reliability of the microcomputer application system can be improved.

### 2. Details of Embodiments

The embodiments will be described more specifically.

### First Embodiment

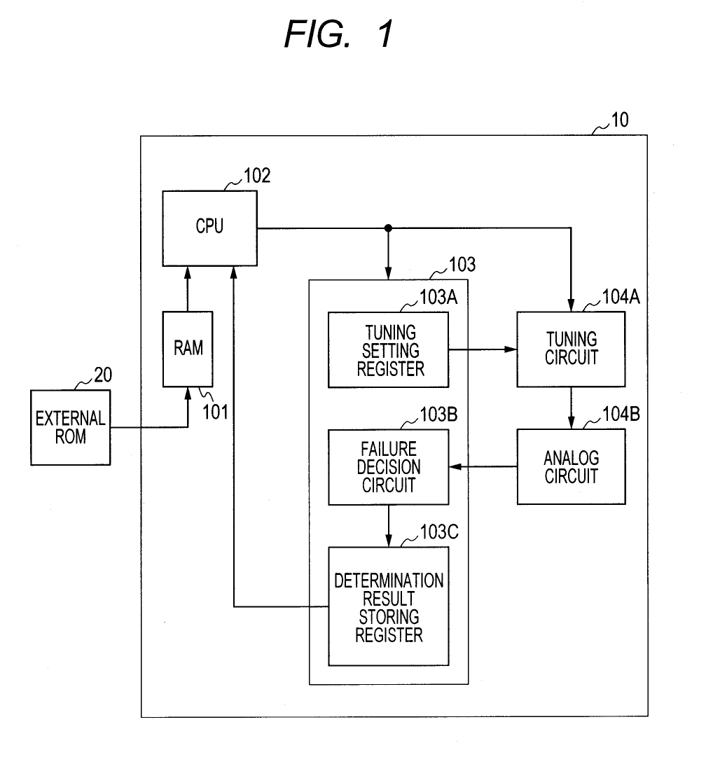

FIG. 1 shows a microcomputer as an example of a semiconductor device according to the present invention. A microcomputer 10 shown in FIG. 1 is formed on a single semiconductor substrate such as a single-crystal silicon substrate by a known semiconductor integrated circuit manufacturing technique. The microcomputer 10 includes a RAM (Random Access Memory) 101, a CPU (Central Processing Unit) 102, a failure detection circuit 103, a tuning circuit 104A, and an analog circuit 104B. To the RAM 101, a failure determination program is transferred from an external ROM (Read Only Memory) 20. The CPU 102 executes the failure determination program in the RAM 101 to control the operation of the failure detection circuit 103 and the tuning circuit 104A. The failure detection circuit 103 includes a tuning setting register 103A, a failure determination circuit 103B, and a determination result storing register 103C. In the tuning setting register 103A, tuning information is set by the CPU 102. The failure determination circuit 103B performs a failure determination on the analog circuit 104B. The analog circuit 104B is a circuit to be subjected to failure detection. In the determination result storing register 103C, a result of the failure determination in the analog circuit 104B is stored. The tuning circuit 104A tunes an analog amount such as voltage, current signal delay time, or the like in accordance with the tuning information which is set in the tuning setting register 103A. A change in the analog amount in the analog circuit 104B is changed by the tuning of the tuning circuit 104A. The operation state of the analog circuit 104B is transmitted to the failure determination circuit 103B.

In the configuration, after the tuning information is set in the tuning setting register 103A by the CPU 102, the circuit 104B to be subjected to failure detection is started by the CPU 102. The analog circuit 104B operates and a result of the operation is transmitted to the failure determination circuit 103B. The failure determination circuit 103B performs a failure determination on the basis of the change in the analog amount in the analog circuit 104B and outputs a result of the determination. The determination result is stored in the determination result storing register 103C. The information in the register 103C is read by the CPU 102. The CPU 102 determines whether a failure occurs or not on the basis of the information in the register 103C.

In the case where the failure determination is made before shipment of the microcomputer 10, the failure detection ratio of shipments can be improved.

Also in the state where the microcomputer 10 is mounted on a user system, the failure determination as described above can be made. For example, by transferring a failure determination program provided by the user to the RAM 101 and making the CPU 102 execute the program, the above-described failure determination can be properly executed in the user system. In this case, the user system can be configured so that the CPU 102 displays an error as the failure determination result to the end user. The end user repairs or replaces the board on which the microcomputer 10 is mounted. In the case where there is a backup system, the system may be replaced with the backup system.

### Second Embodiment

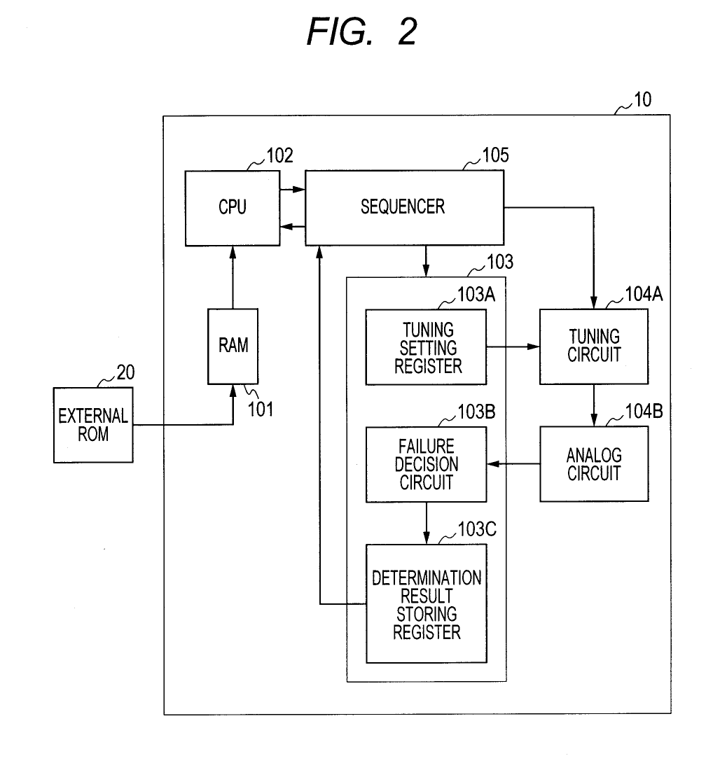

FIG. 2 shows another configuration example of a microcomputer as an example of the semiconductor device according to the present invention.

The microcomputer 10 shown in FIG. 2 is largely different from that shown in FIG. 1 with respect to the point that a sequencer 105 is provided. When the sequencer 105 receives a command indicative of start of determination of a failure in the analog circuit from the CPU 102, the sequencer 105 sequentially controls the operation of the failure detection circuit 103 and the tuning circuit 104A, thereby executing a failure determination. The failure determination result is transmitted to the CPU 102 via the sequencer 105. The CPU 102 determines whether there is a failure or not on the basis of the failure determination result transmitted from the sequencer 105.

In the case where the sequencer 105 is provided and the failure determination is executed by controlling the operations of the failure detection circuit 103 and the circuit 104 to be subjected to failure detection by the sequencer 105, the load on the CPU 102 can be lessened as compared with the configuration illustrated in FIG. 1.

### Third Embodiment

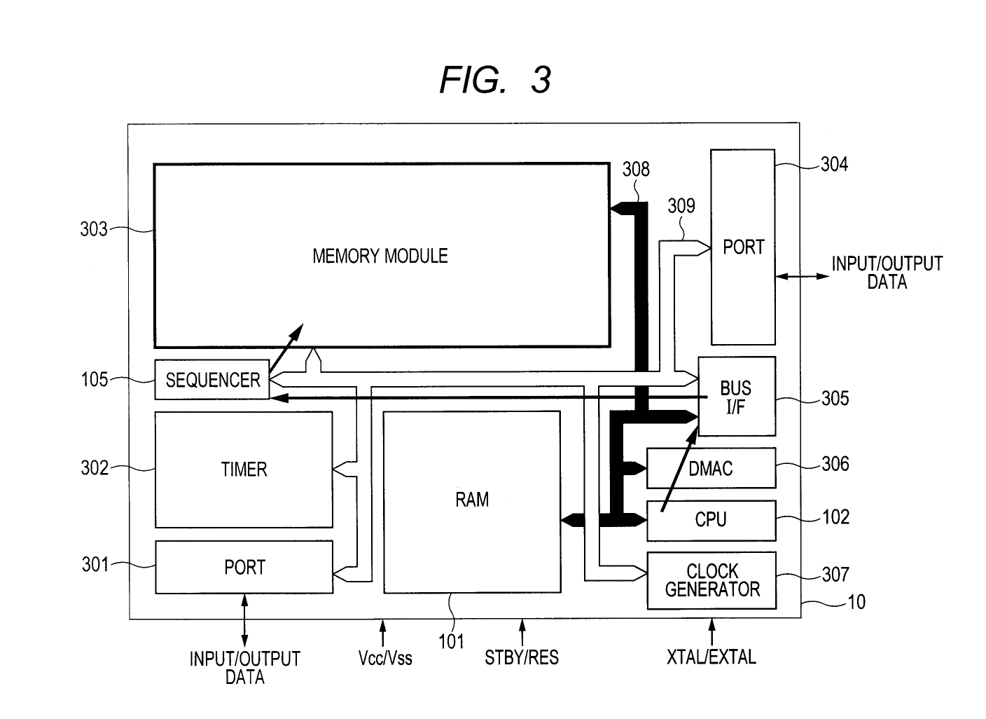

FIG. 3 shows another configuration example of the microcomputer 10 as an example of the semiconductor device according to the present invention.

The microcomputer 10 shown in FIG. 3 includes, in addition to the CPU 102 and the sequencer 305, ports 301 and 304, a timer 302, a flash memory module 303, a bus interface (bus IF) 305, a DMAC (Direct Memory Access Controller) 306, and a clock generator 307. The ports 301 and 309, the timer 302, the sequencer 105, the flash memory module 303, the bus interface 305, and the clock generator 307 are coupled to one another via a periphery bus 309. The RAM 101, the flash memory module 303, the bus interface 305, the DMAC 306, and the CPU 102 are coupled to one another via a high-speed bus 308. The ports 301 and 304 transmit/receive various data to/from the outside. The timer 302 has the function of detecting lapse of predetermined time by counting clocks. The DMAC 306 performs control for directly transferring data among various devices without the CPU 102. The clock generator 307 has an oscillator that oscillates at a predetermined frequency when a quartz crystal oscillator is coupled to a terminal XTAL/EXTAL. When a standby signal STBY is asserted, the microcomputer 10 enters a standby state. When a reset signal RES is asserted, the microcomputer 10 is initialized. As power source voltages for operation of the microcomputer 10, a high-potential-side power source Vcc and low-potential-side power source Vss are supplied via a predetermined terminal.

The sequencer 105 sequentially controls the units for detecting a failure in the circuit to be subjected to failure detection. The circuit subjected to failure detection is an n-channel-type MOS transistor for reference in the memory module 303.

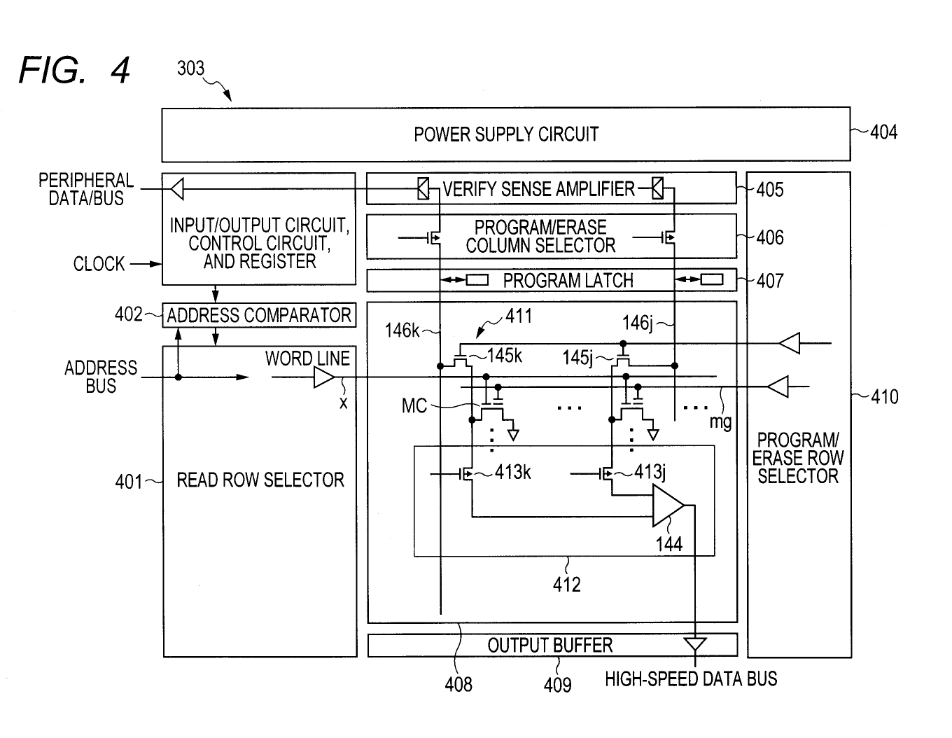

FIG. 4 shows a configuration example of the flash memory module 303.

The flash memory module 303 includes a read row selector 401, an address comparator 402, an input/output circuit, control circuit, and register 403, a power supply circuit 404, a verify sense amplifier 405, a program/erase column selector 406, a program latch 407, a memory mat unit 408, an output buffer 409, and a program/erase row selector 410. The read row selector 401 selects a row (word) in the read system on the basis of a result of decoding of an address signal transmitted via an address bus. The address comparator 402 compares transmitted address signals. The input/output circuit, control circuit, and register 403 control output/reception of data to/from the peripheral data bus synchronously with input clock signals. The power supply circuit 404 generates voltages of various levels used in the flash memory module 303. The verify sense amplifier 405 determines a signal for performing verification at the time of writing data to the memory mat unit 408. The program/erase column selector 306 selects a program/erase column (bit line). The program latch 407 temporarily holds write data. The memory mat unit 408 is configured by arranging a plurality of memory mats. The output buffer 409 outputs data read from the memory mat unit 408 to the outside (high-speed data bus). The program/erase row selector 410 selects a row in a program/erase system (memory gate selection line) on the basis of a result of decoding an address signal transmitted via the address bus.

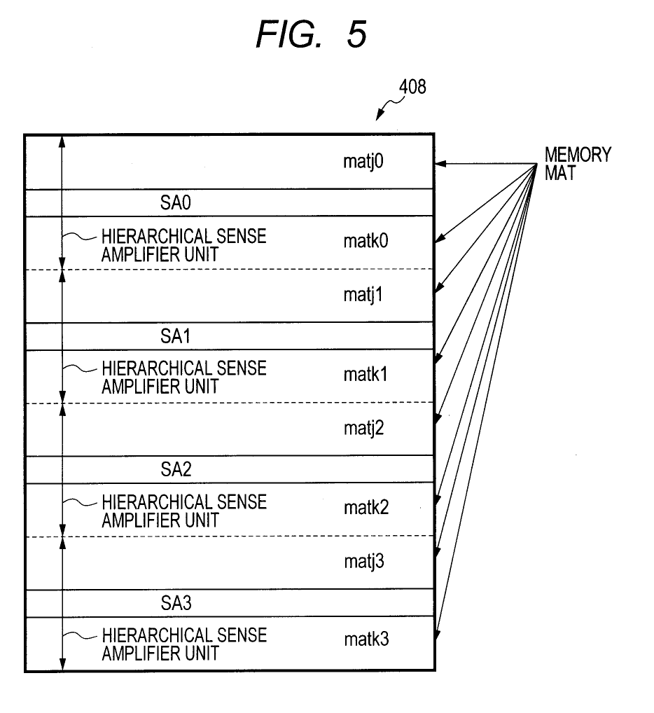

In the memory mat unit 408, for example, as shown in FIG. 5, hierarchical sense amplifiers SA0 to SA3 and memory mats matj0 to matj3 and matk0 to matk3 corresponding to the hierarchical sense amplifiers SA0 to SA3 are arranged. In each of the hierarchical sense amplifier amplifiers SA0 to SA3, a plurality of sense amplifiers are disposed. FIG. 4 shows a main configuration of the memory mat in the memory mat unit 408. The memory mat includes a memory array 411 and a read system circuit 412. The memory array 411 is obtained by arranging a plurality of memory cells MC in a row direction and a column direction. The memory cell MC has electrodes of a control gate, a floating gate, a drain, and a source. The drains of the plurality of memory cells MC arranged in the column direction are commonly coupled and are coupled to a bit line 146k or 146j via a sub bit line selector 145k or 145j. The sources of the plurality of memory cells MC are coupled to a common source line. The source line is configured so as be able to be coupled to the ground potential (low-potential-side power source Vss) via a change-over switch. When the change-over switch is turned off, the source of the memory cell MC is set to an open state. The memory cells MC coupled to the common source line configure one block and are formed as an erase unit in a common well region in a semiconductor substrate. On the other hand, control gates of a plurality of memory cells MC arranged in the row direction are coupled on the row unit basis to a word line “x”. The word line “x” is coupled to the read row selector 401. The floating gates of the plurality of memory cells MC arranged in the row direction are coupled in the row unit basis to a memory gate selection line mg. The memory gate selection line mg is coupled to the program/erase row selector 410. The read circuit 412 includes read column selectors 143k and 143j and a hierarchical sense amplifier circuit 144.

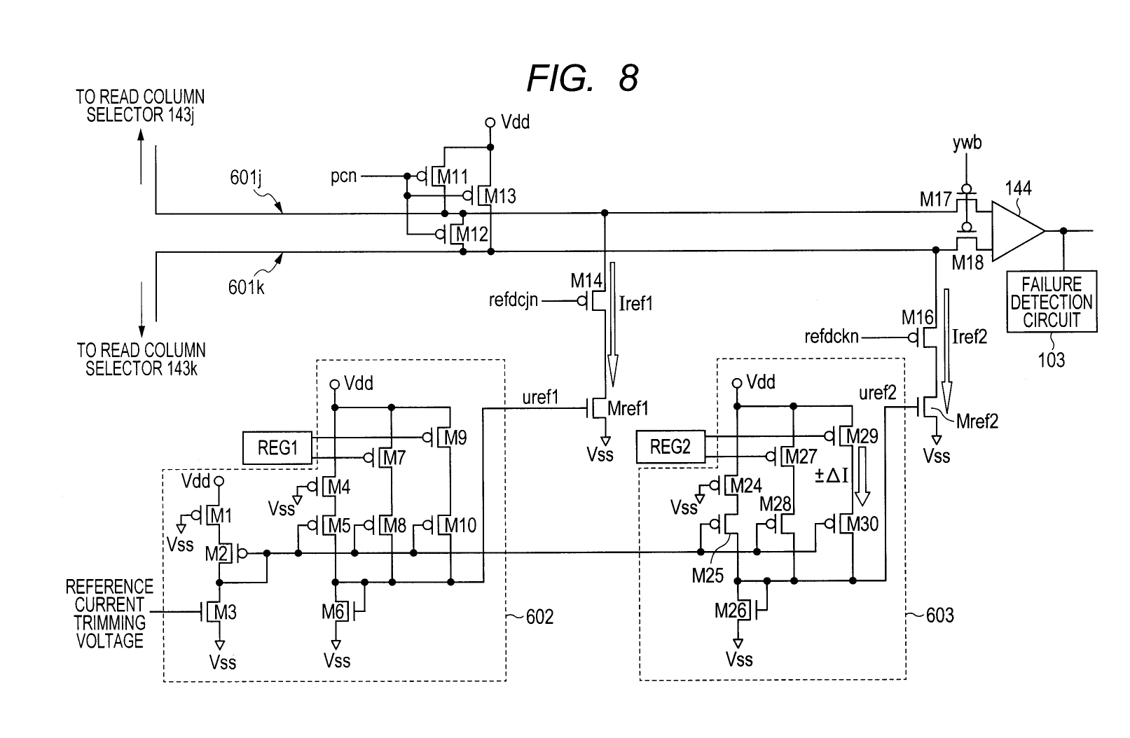

FIG. 8 illustrates a detailed configuration example of the peripheral part of the hierarchical sense amplifier circuit 144.

The input terminals of the hierarchical sense amplifier circuit 144 are coupled to sub bit lines 601j and 601k via p-channel MOS transistors M17 and M18 whose operation is controlled by a control signal ywb. The sub bit line 601j is coupled to the read column selector 143j, and the sub bit line 601k is coupled to the read column selector 143k. To the sub bit lines 601j and 601k, p-channel-type MOS transistors M11, M12, and M13 for precharging the sub bit lines are coupled. The sub bit line 601j is coupled to the high-potential-side power source Vdd via the p-channel-type MOS transistor M11, and the sub bit line 601k is coupled to the high-potential-side power source Vdd via the p-channel-type MOS transistor M13. The sub bit line 601j is coupled to the sub bit line 601k via the p-channel-type MOS transistor M12. When a precharge signal “pcn” is asserted to the low level, the sub-bit lines are precharged.

The sub bit line 601j is coupled to the drain of a first reference n-channel-type MOS transistor Mref1 via a p-channel-type MOS transistor M14, and the sub bit line 601k is coupled to the drain of a second reference n-channel-type MOS transistor Mref2 via a p-channel-type MOS transistor M16. The sources of the first and second reference n-channel-type MOS transistors Mref1 and Mref2 are coupled to the low-potential-side power source Vss. The operation of the p-channel-type MOS transistor M14 is controlled by a reference current control signal refdcjn, and the operation of the p-channel-type MOS transistor M16 is controlled by a reference current control signal refdckn. The first reference n-channel-type MOS transistor Mref1 is controlled by a first reference voltage uref1. The second reference n-channel-type MOS transistor Mref2 is controlled by a second reference voltage uref2. The first and second reference voltages uref1 and uref2 are generated by reference voltage generating circuits 602 and 603, respectively.

The reference voltage generating circuit 602 is obtained by coupling p-channel-type MOS transistors M1, M2, M4, M5, M7, M8, M9 and M10 and n-channel-type MOS transistors M3 and M6. The p-channel-type MOS transistors M1 and M2 and the n-channel-type MOS transistor M3 are coupled in series. The source of the p-channel-type MOS transistor M1 is coupled to the high-potential-side power source Vdd, and the source of the n-channel-type MOS transistor M3 is coupled to the low-potential-side power source Vss. A reference current trimming voltage is supplied to the gate of the n-channel-type MOS transistor M3. The p-channel-type MOS transistors M4 and M5 are coupled to each other in series, the p-channel-type MOS transistors M7 and M8 are coupled to each other in series, and the p-channel-type MOS transistors M9 and M10 are coupled to each other in series. The gate of the p-channel-type MOS transistor M4 is coupled to the low-potential-side power source Vss. To the gate electrodes of the p-channel-type MOS transistors M7 and M9, an output of a register REG1 is transmitted. The register REG1 has a 2-bit configuration corresponding to the p-channel-type MOS transistors M7 and M9. By a setting in the register REG1, the p-channel-type MOS transistors M7 and M9 can be individually turned on/off. The gates of the p-channel-type MOS transistors M5, M8, and M10 are coupled to the gate and the drain of the p-channel-type MOS transistor M2. The drains of the p-channel-type MOS transistors M5, M8, and M10 are coupled to the low-potential-side power source Vss via the n-channel-type MOS transistor M6. The first reference voltage uref1 is obtained from a series connection node of the p-channel-type MOS transistors M5, M8, and M10 and the n-channel-type MOS transistor M6. The first reference voltage uref1 is transmitted to the gate of the first reference n-channel-type MOS transistor Mref1.

The reference voltage generating circuit 603 is obtained by coupling p-channel-type MOS transistors M24, M25, M27, M28, M29, and M30 and an n-channel-type MOS transistor M26. The p-channel-type MOS transistors M24 and M25 are coupled in series, the p-channel-type MOS transistors M27 and M28 are coupled in series, and the p-channel-type MOS transistors M29 and M30 are coupled in series. The gate of the p-channel-type MOS transistor M24 is coupled to the low-potential-side power source Vss. To the gate electrodes of the p-channel-type MOS transistors M27 and M29, an output of a register REG2 is transmitted. The register REG2 has a 2-bit configuration corresponding to the p-channel-type MOS transistors M27 and M29. By a setting in the register REG2, the p-channel-type MOS transistors M27 and M29 can be individually turned on/off. The gates of the p-channel-type MOS transistors M25, M28, and M30 are coupled to the gate and the drain of the p-channel-type MOS transistor M2 in the reference voltage generating circuit 602. The drains of the p-channel-type MOS transistors M25, M28, and M30 are coupled to the low-potential-side power source Vss via the n-channel-type MOS transistor M26. The second reference voltage uref2 is obtained from a series connection node of the p-channel-type, MOS transistors M25, M28, and M30 and the n-channel-type MOS transistor M26. The second reference voltage uref2 is transmitted to the gate of the second reference n-channel-type MOS transistor Mref2.

A first reference current Iref1 flowing in the p-channel-type MOS transistor M14 and the first reference n-channel-type MOS transistor Mref1 and a second reference current Iref2 flowing in the p-channel-type MOS transistor M16 and the second reference n-channel-type. MOS transistor Mref2 can be trimmed by changing the level of reference current trimming voltage. By making settings in the registers REG1 and REG2, the level of the first reference voltage uref1 and that of the second reference voltage uref2 can be individually changed. By changing the values of the first and second reference voltages uref1 and 2, the values of the first and second reference currents Iref1 and Iref2 can be changed. Settings in the registers REG1 and REG2 can be made by the CPU 102 or the sequencer 105.

For example, in a state where the p-channel-type MOS transistor M7 is turned on and the p-channel-type MOS transistor M9 is turned off by the setting in the register REG1, the reference current Iref1 is expressed by the following equation.

Iref1=Iref2 Equation 1

In a state where both of the p-channel-type MOS transistors M7 and M9 are turned on by the setting in the register REG1, the reference current Iref1 is expressed by the following equation.

Iref1=Iref2+ [symbol] | Equation 2

In a state where both of the p-channel-type MOS transistors M7 and M9 are turned off by the setting in the register REG1, the reference current Iref1 is expressed by the following equation.

Iref1=Iref2− [symbol] | Equation 3

Similarly, in a state where the p-channel-type MOS transistor M27 is turned on and the p-channel-type MOS transistor M29 is turned off by the setting in the register REG2, the reference current Iref2 is expressed by the following equation.

Iref2=Iref1 Equation 4

In a state where both of the p-channel-type MOS transistors M27 and M29 are turned on by the setting in the register REG2, the reference current Iref2 is expressed by the following equation.

Iref2=Iref1+ [symbol] | Equation 5

In a state where both of the p-channel-type MOS transistors M27 and M29 are turned off by the setting in the register REG2, the reference current Iref1 is expressed by the following equation.

Iref2=Iref1− [symbol] | Equation 6

To reduce the probability that the first reference n-channel-type MOS transistor Mref1 and the second reference n-channel-type MOS transistor Mref2 fail at the same time, it is preferable to form the first and second reference n-channel-type MOS transistors Mref1 and Mref2 so as to be apart from each other as much as possible.

Data is read from the memory cell MC by the following procedure.

When the control signal ywb is set to the low level to turn on the p-channel-type MOS transistors M17 and M18 and the precharge signal pcn is asserted to the low level to turn on the p-channel-type MOS transistors M11, M12, and M13, the sub bit lines 601j and 601k are precharged. When the reference current control signal refdcjn is set to the low level, the reference current control signal refdckn is set to the high level, and thd precharge signal pcn is set to the high level, in a state where precharging of the sub bit lines 601j and 601k is finished, the hierarchical sense amplifier circuit 144 is started, and the potential difference between the sub bit lines 601j and 601k is sensed. In the case where memory current (Imem) flowing through the sub bit line 601k is smaller than the reference current (Iref)) flowing via the sub bit line 601j, read data is set to the logical value “0”. On the contrary, when the memory current (Imem) flowing via the sub bit line 601k is larger than the reference current (Iref)) flowing via the sub bit line 601j, the read data is set to the logical value “1”.

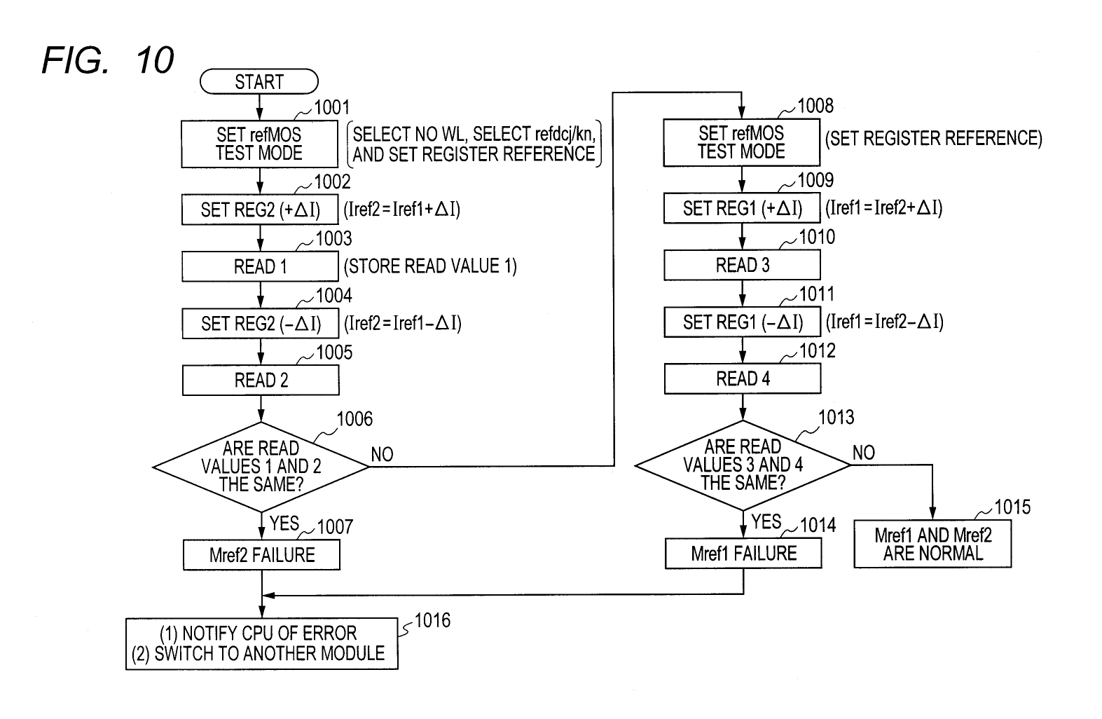

Next, a procedure of detecting a failure in the first reference n-channel-type MOS transistor Mref1 or the second reference n-channel-type MOS transistor M43f2 will be described with reference to FIG. 10.

FIG. 10 shows a procedure of detecting a failure in the first and second reference n-channel-type MOS transistors Mref1 and Mref2.

First, a mode of testing the first and second reference n-channel-type MOS transistors Mref1 and Mref 2 is set in the microcomputer 10 (1001). In the test mode, all of the word lines “x” are set to a non-selection state and the memory cell current (Imem) is not passed. At this time, a setting is made in the register REG2 so that the second reference current Iref2 becomes equal to the first reference current Iref1. By asserting the precharge signal pcn to the low level, the sub bit lines 601j and 601k are precharged. By setting the reference current control signal ref dckn to the low level, the p-channel-type MOS transistor M16 is turned on. The register REG2 is set so that Iref1+ΔI flows as the second reference current Iref2 (1002). On completion of precharging of the sub bit lines 601j and 601k, the precharge signal pcn is negated to the high level. After the precharge signal pcn is negated to the high level, the level difference between the sub bit lines 601j and 601k is sensed by the hierarchical sense amplifier circuit 144 (1003). The output state of the hierarchical sense amplifier circuit 144 is stored in a proper register in the failure detection circuit 103.

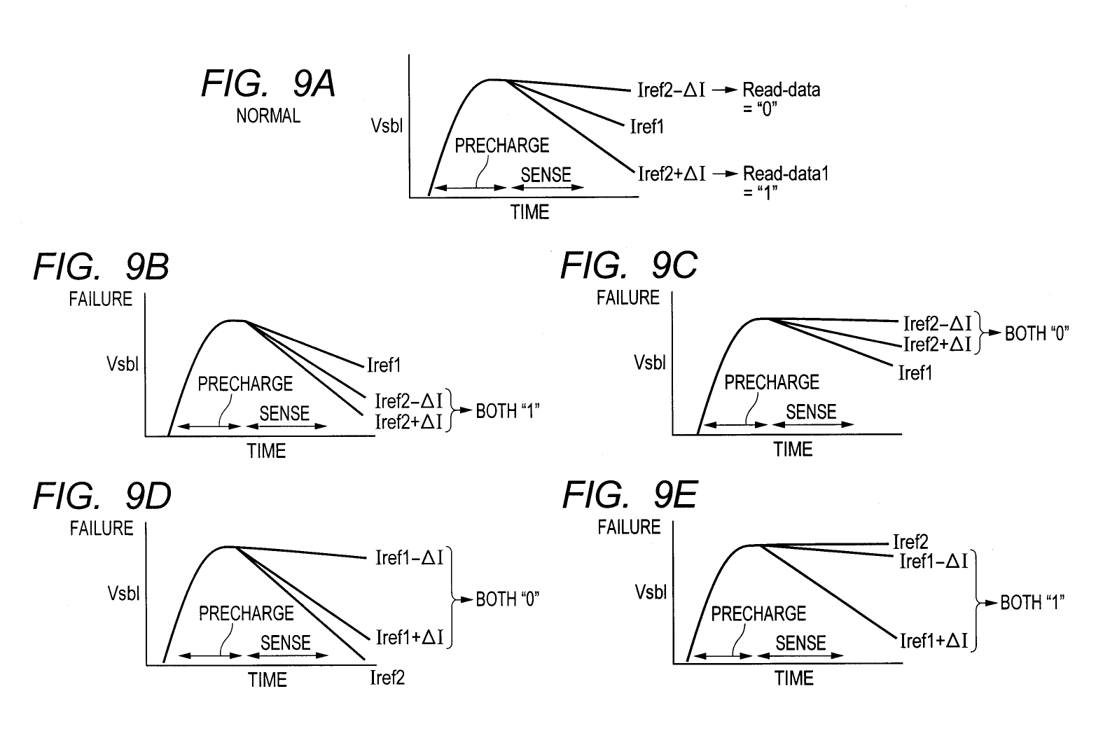

Next, by asserting the precharge signal pcn to the low level, the sub bit lines 601j and 601k are precharged. The register REG2 is set so that Iref1−ΔI flows as the second reference current Iref 2 (1004). On completion of precharging of the sub bit lines 601j and 601k, the precharge signal pcn is negated to the high level. After the precharge signal pcn is negated to the high level, the level difference between the sub bit lines 601j and 601k is sensed by the hierarchical sense amplifier circuit 144 (1005). The output state of the hierarchical sense amplifier circuit 144 is stored in a proper register in the failure detection circuit 103. The value obtained in the step 1003 (the output of the sense amplifier circuit) and the value obtained in the step 1005 (the output of the sense amplifier circuit) are compared in the failure detection circuit 103. When both of the values are equal to each other in the comparison, it is determined that the second reference n-channel-type MOS transistor Mref2 fails (1007). The comparison in step 1006 includes the case where the both values having the logical value “0” are equal to each other (refer to FIG. 9D) and the case where the both values having the logical value “1” are equal to each other (refer to FIG. 9E).

Subsequently, the test mode is set again (1008). The register REG1 is set so that the first reference current Iref1 becomes equal to the second reference current Iref2. By asserting the precharge signal pcn to the low level, the sub bit lines 601j and 601k are precharged. By setting the reference current control signal refdcjn to the low level, the p-channel-type MOS transistor M14 is turned on. The register REG1 is set so that Iref2+ΔI flows as the first reference current Iref1 (1009). On completion of precharging of the sub bit lines 601j and 601k, the precharge signal pcn is negated to the high level. After the precharge signal pcn is negated to the high level, the level difference between the sub bit lines 601j and 601k is sensed by the hierarchical sense amplifier circuit 144 (1010). The output state of the hierarchical sense amplifier circuit 144 is stored in a proper register in the failure detection circuit 103.

Next, by asserting the precharge signal pcn to the low level, the sub bit lines 601j and 601k are precharged. The register REG1 is set so that Iref2−ΔI flows as the first reference current Iref1 (1011). On completion of precharging of the sub bit lines 601j and 601k, the precharge signal pcn is negated to the high level. After the precharge signal pcn is negated to the high level, the level difference between the sub bit lines 601j and 601k is sensed by the hierarchical sense amplifier circuit 144 (1012). The output state of the hierarchical sense amplifier circuit 144 is stored in a proper register in the failure detection circuit 103. The value obtained in the step 1010 (the output of the sense amplifier circuit) and the value obtained in the step 1012 (the output of the sense amplifier circuit) are compared in the failure detection circuit 103. When both of the values are equal to each other in the comparison, it is determined that the first reference n-channel-type MOS transistor Mref1 fails (1014). The comparison in step 1013 includes the case where the both values having the logical value “1” are equal to each other (refer to FIG. 9B) and the case where the both values having the logical value “0” are equal to each other (refer to FIG. 9C). In the case where both of the values are not equal to each other in the comparison in the step 1013 (refer to FIG. 9A), it is determined that both of the first and second reference n-channel-type MOS transistors Mref1 and Mref 2 are normal (1015).

The failure determination can be made by a procedure similar to the above on all of the first and second reference n-channel-type MOS transistors Mref1 and Mref2 in the memory module 303.

In the case where both of the values are equal to each other in the comparison in the step 1006 or 1013, an error is notified to the CPU 102. In this case, in a manner similar to the first embodiment, the user system can be configured so that the CPU 102 displays an error as a failure determination result by an error process based on the error notification and notifies the end user of the error. The end user repairs or replaces the board on which the microcomputer 10 is mounted. In the case where there is a backup system, the system may be replaced with the backup system.

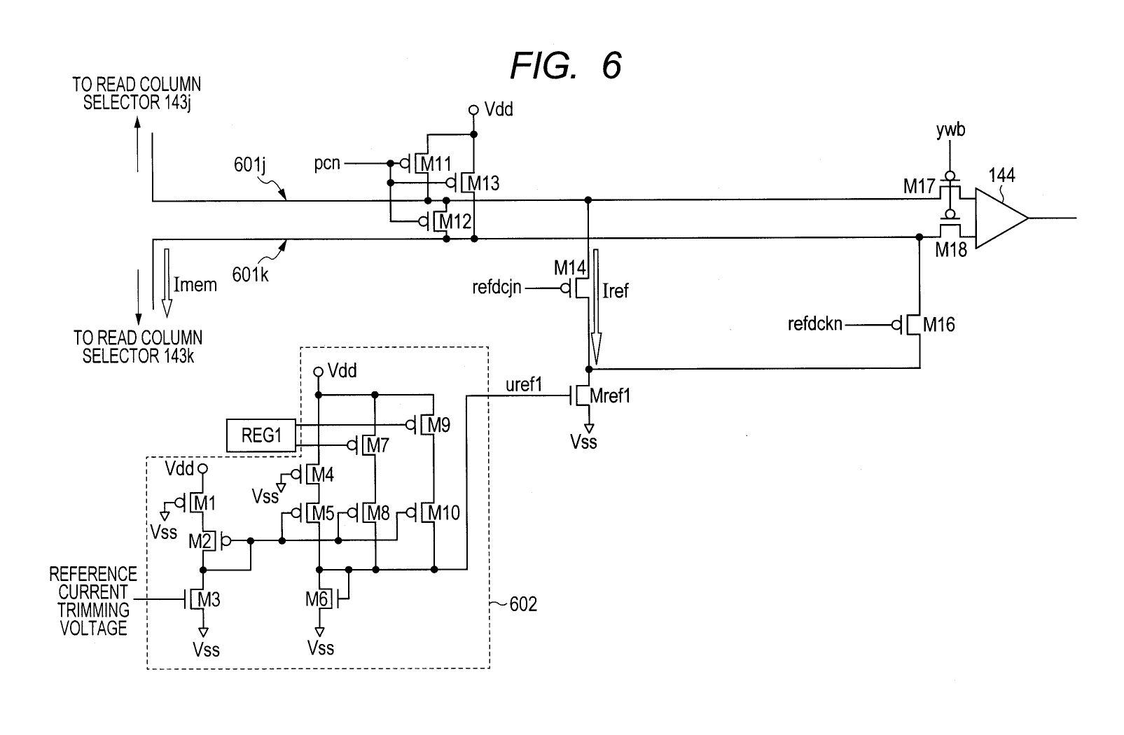

FIG. 6 shows a circuit configuration to be compared with the circuit illustrated in FIG. 8.

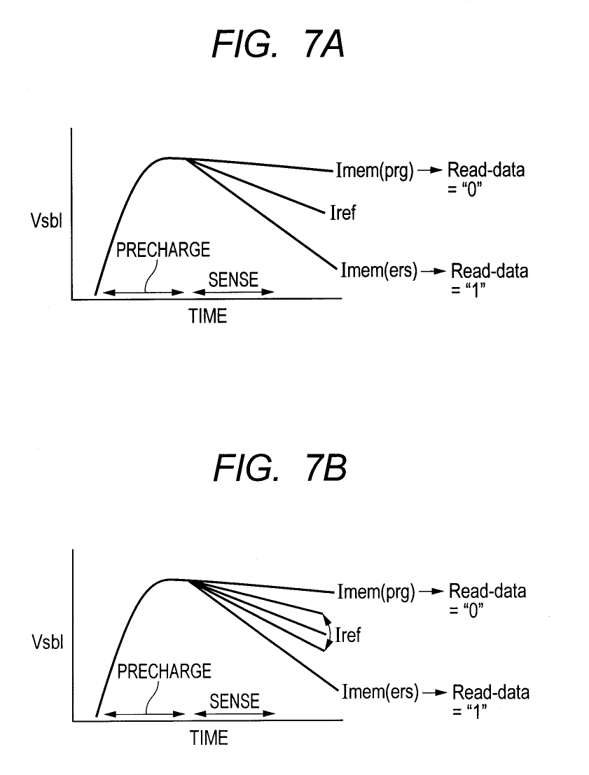

The circuit shown in FIG. 6 is largely different from that shown in FIG. 8 with respect to the point that the register REG2 and the reference voltage generating circuit 603 are not provided and the drains of the p-channel-type MOS transistors M14 and M16 are commonly coupled to the drain of the reference n-channel-type MOS transistor Mref1. In the configuration, in the case where the reference n-channel-type MOS transistor Mref1 does not fail, when the memory current (Imem) flowing through the sub bit line 601k is smaller than the reference current (Iref)) flowing via the sub bit line 601j as shown in FIG. 7A, read data is set to the logical value “0”. On the contrary, when the memory current (Imem) flowing via the sub bit line 601k is larger than the reference current (Iref)) flowing via the sub bit line 601j, the read data is set to the logical value “1”.

Even if the reference n-channel-type MOS transistor Mref1 fails and, for example, as illustrated in FIG. 7B, the reference current (Iref)) flowing via the sub bit line 601j increases/decreases slightly, if there is a current difference (AI) to a certain extent between the memory current (Imem) and the reference current (Iref), the data can be read. Consequently, whether the reference n-channel-type MOS transistor Mref1 fails or not cannot be determined. For example, in the memory module 303 mounted on the microcomputer 10 of recent years, hundreds of the reference n-channel-type MOS transistors Mref1 are provided. In the case where the circuit configuration shown in FIG. 6 is employed, it is difficult to monitor the reference currents (Iref)) of all of the reference n-channel-type MOS transistors Mref1.

In contrast, the configuration shown in FIG. 8 is obtained by adding the register REG2 and the reference voltage generating circuit 603 to the circuit configuration shown in FIG. 6, and the reference current Iref1 flowing in the first reference n-channel-type MOS transistor Mref1 and the reference current Iref2 flowing in the second reference n-channel-type MOS transistor Mref2 can be changed individually. As a result, according to the failure detection procedure shown in FIG. 10, failures in the first and second reference n-channel-type MOS transistors Mref1 and Mref2 can be detected. By the failure determination, a defect to be described below of an n-channel-type MOS transistor for reference can be determined.

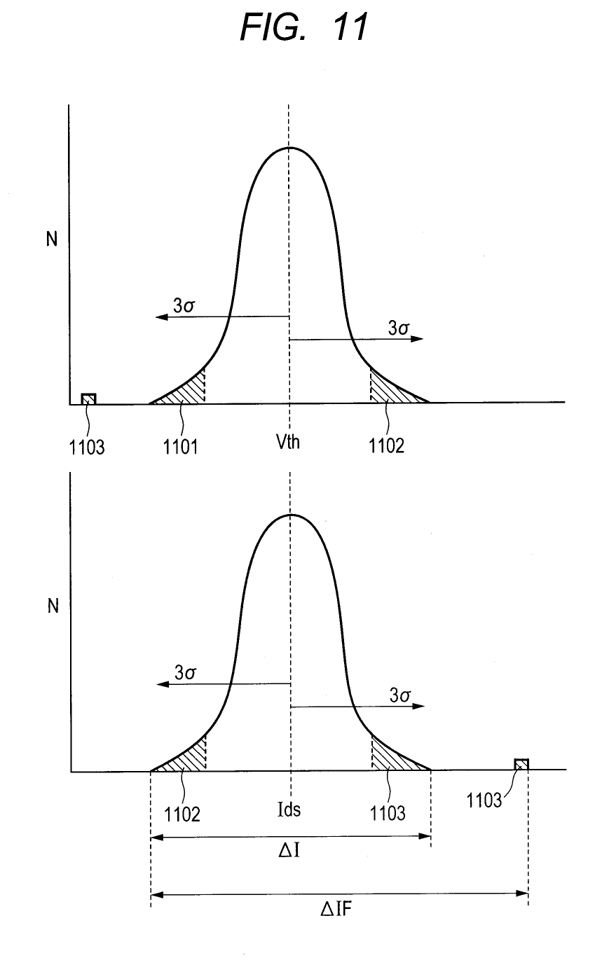

FIG. 11 shows an object of failure detection of an n-channel-type MOS transistor for reference.

Due to process variations, a threshold Vth of the MOS transistor is distributed by 3σ between 1101 to 1102 in FIG. 11. Ids is also similarly distributed by 3σ. It is desired to detect a MOS transistor distributed in 1103 slightly out of 3σ. There are hundreds of the n-channel-type MOS transistors for reference in a module, and it is unrealistic to measure the current of each of the transistors. In addition, the memory current amount cannot be set to a predetermined value. Consequently, in the circuit configuration shown in FIG. 6, even if an n-channel-type MOS transistor for reference distributed in 1103 in the diagram exists, it is difficult to remove it as a defective. In contrast, in the configuration shown in FIG. 8, by using the difference of reference currents as described above, the n-channel-type MOS transistor for reference distributed in 1103 in the diagram can be determined as failed one.

### Fourth Embodiment

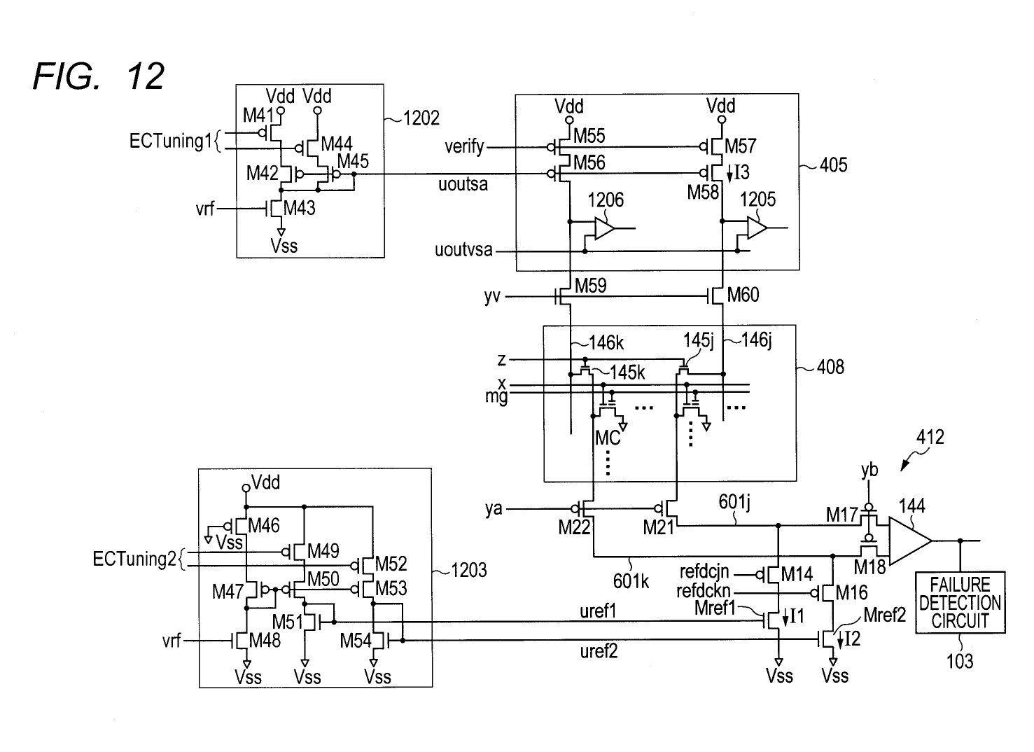

FIG. 12 shows another configuration example of the main part of the memory module 303 illustrated in FIG. 4.

The verify sense amplifier 405 includes verify sense amplifier circuits 1205 and 1206 provided in correspondence with the bit lines 146j and 146k, and p-channel-type MOS transistors M55 to M58. The p-channel-type MOS transistors M57 and M58 are coupled to each other in series. The source of the p-channel-type MOS transistor M57 is coupled to the high-potential-side power source Vdd, and the drain of the p-channel-type MOS transistor M58 is coupled to one of input terminals of the verify sense amplifier circuit 1205 and is also coupled to the bit line 146j via a p-channel-type MOS transistor M60. The p-channel-type MOS transistors M55 and M56 are coupled to each other in series. The source of the p-channel-type MOS transistor M55 is coupled to the high-potential-side power source Vdd, and the drain of the p-channel-type MOS transistor M56 is coupled to one of input terminals of the verify sense amplifier circuit 1206 and is also coupled to the bit line 146k via a p-channel-type MOS transistor M59. The operation of the p-channel-type MOS transistors M55 and M57 is controlled by a verify mode signal “verify”. The operation of the p-channel-type MOS transistors M56 and M58 is controlled by a VSA verify current PMOS bias voltage uoutsa. The level of the VSA verify current PMOS bias voltage uoutsa is controlled by a VSA verify current PMOS bias voltage generating circuit 1202. To the other input terminal of the verify sense amplifier circuits 1205 and 1206, a VSA comparison voltage uoutvsa is transmitted. The verify sense amplifier circuits 1205 and 1206 determine the potential difference of the bit lines 146j and 146k using the VSA comparison voltage uoutvsa as a reference. The p-channel-type MOS transistors M59 and M60 form the program/erase column selector 406 shown in FIG. 4, and the operation is controlled by a program/erase column selector control signal “yv”. The sub bit lines 601j and 601k are provided with p-channel-type MOS transistors M21 and M22 forming the read column selectors 143j and 143k shown in FIG. 4. The operation of the p-channel-type MOS transistors M21 and M22 is controlled by a column selector control signal “ya”. The operation of the p-channel-type MOS transistors M17 and M18 near the hierarchical sense amplifier circuit 144 is controlled by a column selector control signal “yb”. The operation of the first reference n-channel-type MOS transistor Mref1 is controlled by the HSA reference current NMOS bias voltage uref1, and the operation of the second reference n-channel-type MOS transistor Mref2 is controlled by the HSA reference current NMOS bias voltage uref2. The levels of the HSA reference current NMOS bias voltages uref1 and uref2 are controlled by the reference voltage generating circuit 1203.

The VSA verify current PMOS bias voltage generating circuit 1202 is obtained by coupling p-channel-type MOS transistors M41, M42, M44, and M45 and an n-channel-type MOS transistor M43. The p-channel-type MOS transistors M41 and M42 are coupled to each other in series. The p-channel-type MOS transistors M44 and M45 are coupled to each other in series. The sources of the p-channel-type MOS transistors M41 and M44 are coupled to the high-potential-side power source Vdd, and the p-channel-type MOS transistors M42 and M45 are coupled to the low-potential-side power source Vss via the p-channel-type MOS transistor M43. A predetermined bias voltage vrf is supplied to the gate of the n-channel-type MOS transistor M43. To the gates of the p-channel-type MOS transistors M41 and M44, a current tuning signal ECTuning1 is transmitted. By the current tuning signal ECTuning1, the level of the VSA verify current PMOS bias voltage uoutsa is controlled. In such a meaning, the VSA verify current PMOS bias voltage generating circuit 1202 serves as a tuning circuit. The current tuning signal ECTuning1 is generated by the sequencer 105.

The reference voltage generating circuit 1203 is obtained by coupling p-channel-type MOS transistors M46, M47, M49, M50, M52, and M53 and the n-channel-type MOS transistors M48, M51, and M54. The p-channel-type MOS transistors M46 and M47 and the n-channel-type MOS transistor M48 are coupled to each other in series. The p-channel-type MOS transistors M49 and M50 and the n-channel-type MOS transistor M51 are coupled to each other in series. The p-channel-type MOS transistors M52 and M53 and the n-channel-type MOS transistor M54 are coupled to each other in series. The sources of the p-channel-type MOS transistors M46, M49, and M52 are coupled to the high-potential-side power source Vdd. The sources of the n-channel-type MOS transistors M48, M51, and M54 are coupled to the low-potential-side power supply Vss. The gate and the drain of the p-channel-type MOS transistor M47 are coupled, and the p-channel-type MOS transistors M50 and M53 are current-mirror-coupled. The drain of the p-channel-type MOS transistor M50 and the gate of the n-channel-type MOS transistor M51 are coupled to each other, and the HSA reference current NMOS bias voltage uref1 is taken from the coupling point. The drain of the p-channel-type MOS transistor M53 and the gate of the n-channel-type MOS transistor M54 are coupled to each other, and the HSA reference current NMOS bias voltage uref2 is taken from the coupling point. A current tuning signal ECTuning2 is transmitted to the gate of the p-channel-type MOS transistor M49 and the gate of the p-channel-type MOS transistor M52, and the levels of the HSA reference current NMOS bias voltages uref1 and uref2 are controlled by the current tuning signal ECTuning2. In such meaning, the reference voltage generating circuit 1203 forms the tuning circuit. The current tuning signal ECTuning2 is generated by the sequencer 105.

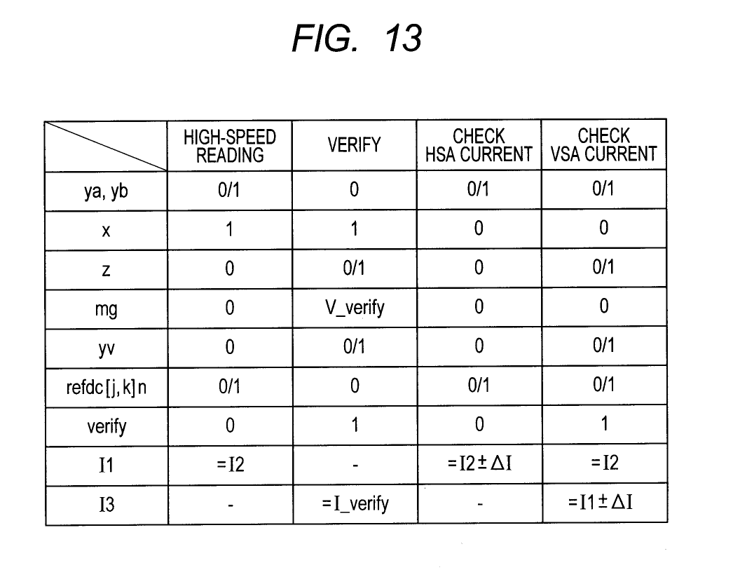

FIG. 13 shows main operations in the memory module 303 with the above-described configuration and states of the signals. The main operations in the memory module 303 include high-speed reading for reading stored data at high speed, verification for verifying a written state, an HSA current check for examining reference current I1 flowing in the first reference n-channel-type MOS transistor Mref1, and a VSA current check for examining current flowing in the p-channel-type MOS transistor M58. In FIG. 13, “0” indicates a non-selection state, “1” indicates a selection state, “0/1” indicates follow of advice, V_verify expresses verify voltage, and I_verify denotes verify current.

The configuration shown in FIG. 12 has sense amplifier circuits of two systems; the verify sense amplifier circuits 1205 and 1206 and the hierarchical sense amplifier circuit 144. Whether the determination currents in the sense amplifier circuits of the two systems are matched or not is an important issue to improve the reliability of data read from the memory module 303. The procedure of determining whether the determination currents are matched or not between the sense amplifier circuits of the two systems or not will be described below.

When the reference current I1 or I2 of the hierarchical sense amplifier circuit 144 and the reference current I3 of the verify sense amplifier circuit 1205 are set to be equal to each other, a check is made to see whether the currents actually match or not. The check can be made by examining the VSA current. The current difference between the memory current Imem and the reference current I3 is determined by the verify sense amplifier circuits 1205 and 1206 at the time of verifying a write state. In the VSA current check, by determining the current difference between the reference currents I1 and I3 by the verify sense amplifier circuit 1205, consistency of the determined currents can be examined.

First, a consistency test is set by the sequencer 105. In the setting, the column selector control signals ya, yb, and yv, reference current control signals refdcjn and refdckn, a sub bit line select signal “z”, and the verify mode signal “verify” are set to the selection level. By the setting, the p-channel-type MOS transistors M21, M22, M17, M18, M14, and M16 and the sub bit line selectors 145j and 145k enter a conductive state. The word line “x” and the memory gate selection line mg are set in a non-selection state.

Next, the current tuning signals ECTuning1 and ECTuning2 are set so that the following equation is satisfied.

I3=I1+ [symbol] I Equation 7

In this state, an output of the verify sense amplifier circuit 1205 is detected by the failure detection circuit 103. When the output of the verify sense amplifier circuit 1205 is the logical value “1”, it is determined that the determination currents are inconsistent under the condition expressed by the equation 7. When the output is the logical value “0”, it is determined that the determination currents are consistent. In the case where it is determined that the determination currents are inconsistent under the condition expressed by the equation 7, the current tuning signals ECTuning1 and ECTuning2 are set so that the following equation is satisfied by the control of the sequencer 105.

I3=I1− [symbol] I Equation 8

In this state, an output of the verify sense amplifier circuit 1205 is detected by the failure detection circuit 103. When the output of the verify sense amplifier circuit 1205 is the logical value “1”, it is determined that the determination currents are inconsistent under the condition expressed by the equation 8. When the output is the logical value “0”, it is determined that the determination currents are consistent.

In the case where the determination currents are consistent under both of the conditions expressed by the equations 7 and 8, the input system of the verify sense amplifier circuit 1205 and the hierarchical sense amplifier circuit 144 operates normally. By determining the consistence of the determination currents between the verify sense amplifier circuit 1205 and the hierarchical sense amplifier circuit 144 as described above, a failure in the input system of the verify sense amplifier circuit 1205 and the hierarchical sense amplifier circuit 144 can be determined. The consistency of the determination currents between the verify sense amplifier circuit 1206 and the hierarchical sense amplifier circuit 144 can be also determined. An output signal of the hierarchical sense amplifier circuit 144 may be examined by the sequencer 105. In the case of examining the output signal of the hierarchical sense amplifier circuit 144 by the failure detection circuit 103, the HSA current check is made (refer to FIG. 13). In this case, first, by setting the current tuning signals ECTuning1 and ECTuning2, the consistency of the determination currents is examined by the condition of the following equation.

I1=I2− [symbol] I Equation 9

Next, by setting the current tuning signals ECTuning1 and ECTuning2, the consistency of the determination currents is examined by the condition of the following equation.

I1=I2+ [symbol] I Equation 10

### Fifth Embodiment

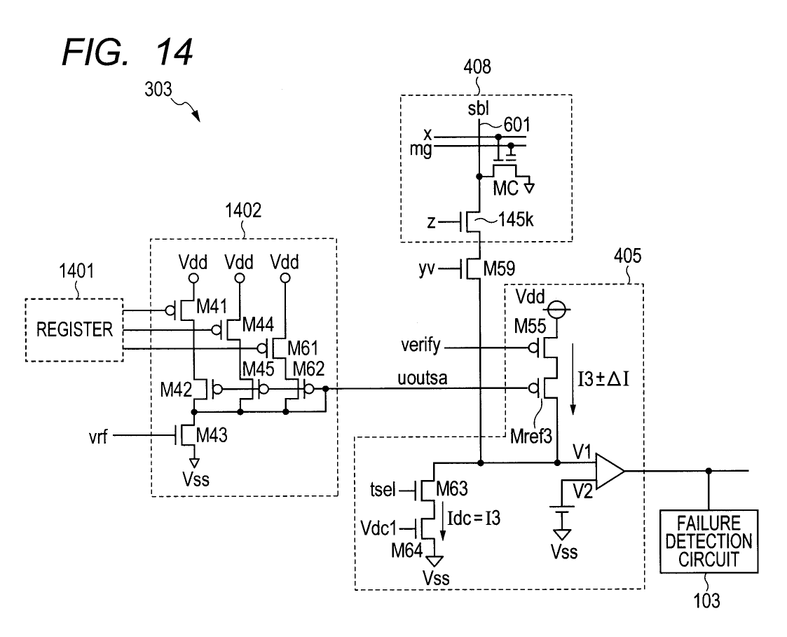

FIG. 14 shows a configuration example of the verify sense amplifier 405 in the memory module 303.

The verify sense amplifier 405 includes the p-channel-type MOS transistor M55, the reference p-channel-type MOS transistor Mref3, the n-channel-type MOS transistors M63 and M64, and the verify sense amplifier circuit 1206. The p-channel-type MOS transistor M55 and the p-channel-type MOS transistor Mref3 for reference are coupled to each other in series. The source of the p-channel-type MOS transistor M55 is coupled to the high-potential-side power source Vdd, and the drain of the p-channel-type MOS transistor Mref3 for reference is coupled to one of input terminals of the verify sense amplifier circuit 1205. To the gate of the p-channel-type MOS transistor M55, the verify mode signal “verify” is transmitted. To the gate of the p-channel-type MOS transistor Mref3 for reference, the VSA verify current PMOS bias voltage uoutsa is transmitted. The VSA verify current PMOS bias voltage uoutsa is generated by the VSA verify current PMOS bias voltage generating circuit 1402. One of the input terminals of the verify sense amplifier circuit 1206 is coupled to the low-potential-side power source Vss via the n-channel-type MOS transistors M63 and M64. A selection signal tse1 is transmitted to the gate of the n-channel-type MOS transistor M63, and a bias voltage Vdc1 is transmitted to the gate of the n-channel-type MOS transistor M64. A predetermined reference voltage V2 is supplied to the other input terminal of the verify sense amplifier circuit 1206. An output of the verify sense amplifier circuit 1206 is transmitted to the failure detection circuit 103.

The VSA verify current PMOS bias voltage generating circuit 1402 is obtained by coupling the p-channel-type MOS transistors M41, M42, M44, M45, M61, and M62 and the n-channel-type MOS transistor M43. The p-channel-type MOS transistors M41 and M42 are coupled to each other in series, the p-channel-type MOS transistors M44 and M45 are coupled to each other in series, and the p-channel-type MOS transistors M61 and M62 are coupled to each other in series. The sources of the p-channel-type MOS transistors M41, M44, and M61 are coupled to the high-potential-side power source Vdd, and the drains of the p-channel-type MOS transistors M42, M45, and M62 are coupled to the low-potential-side power source Vss via the n-channel-type MOS transistor M43. The predetermined bias voltage vrf is supplied to the gate of the n-channel-type MOS transistor M43. To the gates of the p-channel-type MOS transistors M41, M44, and M61, an output value of the register 1401 is transmitted. By the output value of the register 1401, the level of the VSA verify current PMOS bias voltage uoutsa is controlled.

In the configuration, for writing of data to the memory cell MC, the written data is verified on the basis of an output of the verify sense amplifier circuit 1206. Detection of a failure in the p-channel-type MOS transistor Mref3 for reference can be performed as follows.

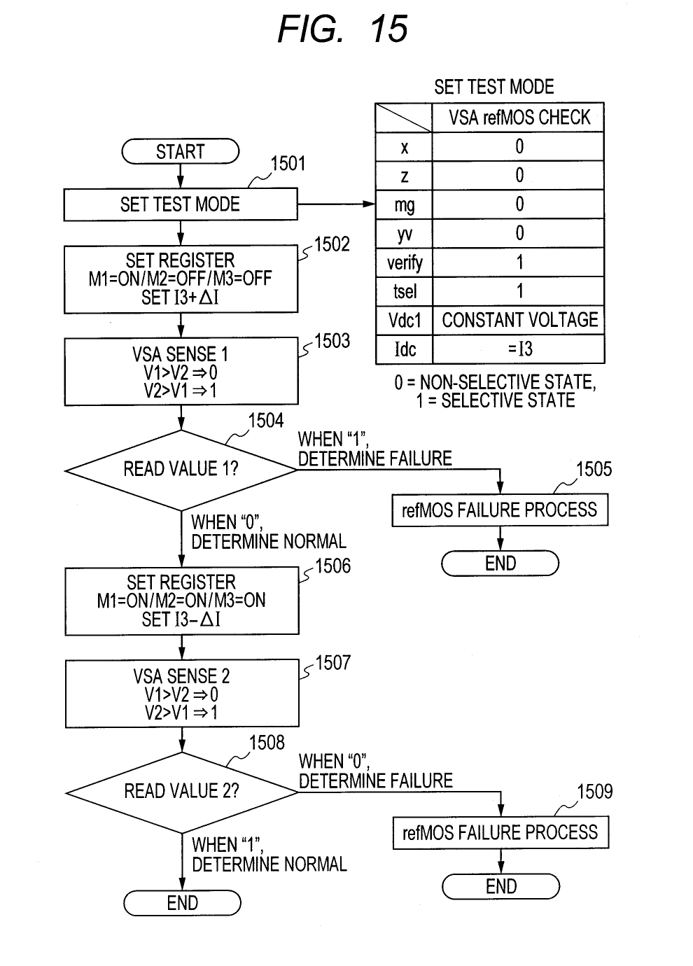

FIG. 15 shows a procedure of detecting a failure in the p-channel-type MOS transistor Mref3 for reference. The procedure of detecting a failure in the p-channel-type MOS transistor Mref3 for reference is basically similar to that of detecting a failure in the n-channel-type MOS transistors Mref1 and Mref2 for reference in FIG. 8.

First, a test mode is set by the sequencer 105 (1501). In the test mode setting, the word line “x”, the sub bit line select signal “z”, the memory gate selection line mg, and the program/erase column selector control signal yv are set to a non-selection state and the verify mode signal “verify” and the selection signal tse1 are set to the selection state. The bias voltage Vdc1 is set to a predetermined value (low voltage). In this state, the register 1401 is set by the sequencer 105 so that the following equation is satisfied (1502).

Idc=I3+ [symbol] I Equation 11

Idc denotes current flowing in the p-channel-type MOS transistor Mref3 for reference and the n-channel-type MOS transistors M63 and M64. In this state, an output of the verify sense amplifier circuit 1206 is transmitted to the failure detection circuit 103, and failure determination is performed. In the case where V1>V2, an output of the verify sense amplifier circuit 1206 is the logical value “0”, and in the case where V1<V2, an output of the verify sense amplifier circuit 1206 is the logical value “1” (1503). In the case where the output of the verify sense amplifier circuit 1206 is the logical value “1”, it is determined that the p-channel-type MOS transistor Mref3 for reference fails (1504), an interrupt request to the CPU 102 is issued, and an interrupt process on the failure of the p-channel-type MOS transistor Mref3 for reference is performed in the CPU 102 (1505). In the case where the output of the verify sense amplifier circuit 1206 is the logical value “0”, it is determined that the p-channel-type MOS transistor Mref3 for reference is normal, and the register 1401 is set by the sequencer 105 so that the following equation is satisfied (1504, 1506).

Idc=I3− [symbol] I Equation 12

In this state, in a manner similar to the above, an output of the verify sense amplifier circuit 1206 is transmitted to the failure detection circuit 103, and failure determination is performed. In the case where V1>V2, an output of the verify sense amplifier circuit 1206 is the logical value “0”, and in the case where V1<V2, an output of the verify sense amplifier circuit 1206 is the logical value “1” (1507). In the case where the output of the verify sense amplifier circuit 1206 is the logical value “0”, it is determined that the p-channel-type MOS transistor Mref3 for reference fails (1508). In this case as well, an interrupt request to the CPU 102 is issued, and an interrupt process on the failure of the p-channel-type MOS transistor Mref3 for reference is performed in the CPU 102 (1509). In the case where the output of the verify sense amplifier circuit 1206 is the logical value “1”, it is determined that the p-channel-type MOS transistor Mref3 for reference is normal. In such a manner, the current Idc flowing in the p-channel-type MOS transistor Mref3 for reference is changed and, on the basis of an output of the verify sense amplifier circuit 1206 at this time, a failure in the p-channel-type MOS transistor Mref3 for reference can be detected.

### Sixth Embodiment

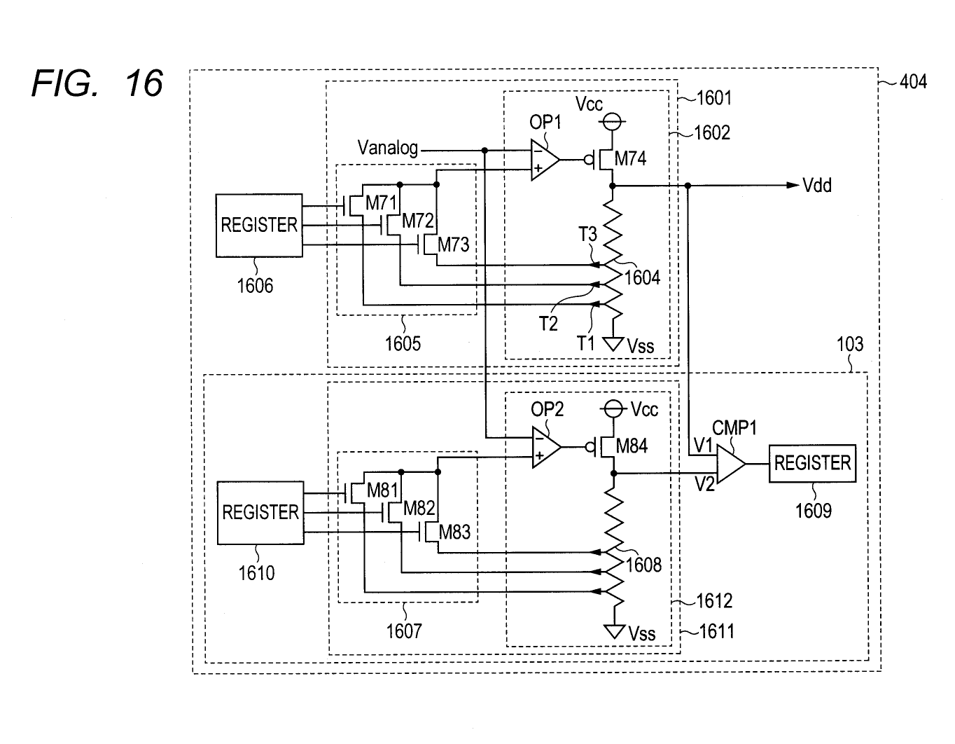

FIG. 16 shows a configuration example of the power supply circuit 404.

The power supply circuit 404 includes a voltage decreasing circuit 1601, a register 1606, and the failure detection circuit 103. The voltage decreasing circuit 1601 includes an analog circuit 1602 and a tuning circuit 1605. The analog circuit 1602 includes an operational amplifier OP1, a p-channel-type MOS transistor M74, and a resistor ladder 1604. The p-channel-type MOS transistor M74 and the resistor ladder 1604 are coupled to each other in series. From the series connection node of the p-channel-type MOS transistor M74 and the resistor ladder 1604, a high-potential-side power source voltage (Vdd) is obtained. The high-potential-side power source voltage (Vdd) is supplied to the components in the microcomputer 10. The source of the p-channel-type MOS transistor M74 is coupled to the high-potential-side power source Vcc supplied from the outside of the microcomputer 10. The other end of the resistor ladder 1604 is coupled to the low-potential-side power source Vss. The resistor ladder 1604 is provided with three voltage dividing terminals T1, T2, and T3. The voltage dividing terminals T1, T2, and T3 are coupled to a non-inversion input terminal (+) of the operational amplifier OP1 via the tuning circuit 1605. The tuning circuit 1605 includes n-channel-type MOS transistors M71, M72, and M73. A reference voltage “Vanalog” is supplied to the inversion input terminal (−) of the operational amplifier OP1. An output of the operational amplifier OP1 is transmitted to the gate of the p-channel-type MOS transistor M74. An output of the register 1606 is transmitted to the gates of the n-channel-type MOS transistors M71, M72, and M73. By setting in the register 1606, the n-channel-type MOS transistors M71, M72, and M73 can be turned off individually. Consequently, the level of a voltage to be fed back to the non-inversion input terminal (+) of the operational amplifier OP1 can be changed.

The failure detection circuit 103 includes a register 1610, a voltage decreasing circuit 1611, a comparator CMP1, and a register 1609. The voltage decreasing circuit 1611 has an analog circuit 1612 including an operational amplifier OP2, a p-channel-type MOS transistor M84, and a resistor ladder 1608, and a tuning circuit 1607 and has the same configuration as that of the voltage decreasing circuit 1601. The tuning circuit 1607 includes n-channel-type MOS transistors M81, M82, and M83. To the gates of the n-channel-type MOS transistors M81, M82, and M83, an output of the register 1610 is transmitted. By setting the register 1610, the n-channel-type MOS transistors M81, M82, and M83 can be individually turned on/off. By the operation, the level of a voltage which is fed back to the non-inversion input terminal (+) of the operational amplifier OP2 can be changed. The comparator CMP1 compares an output voltage (expressed as “V1”) of the voltage decreasing circuit 1601 and an output voltage (expressed as “V2”) of the voltage decreasing circuit 1611. The result of the comparison in the comparator CMP1 is written in the register 1609 at the post stage.

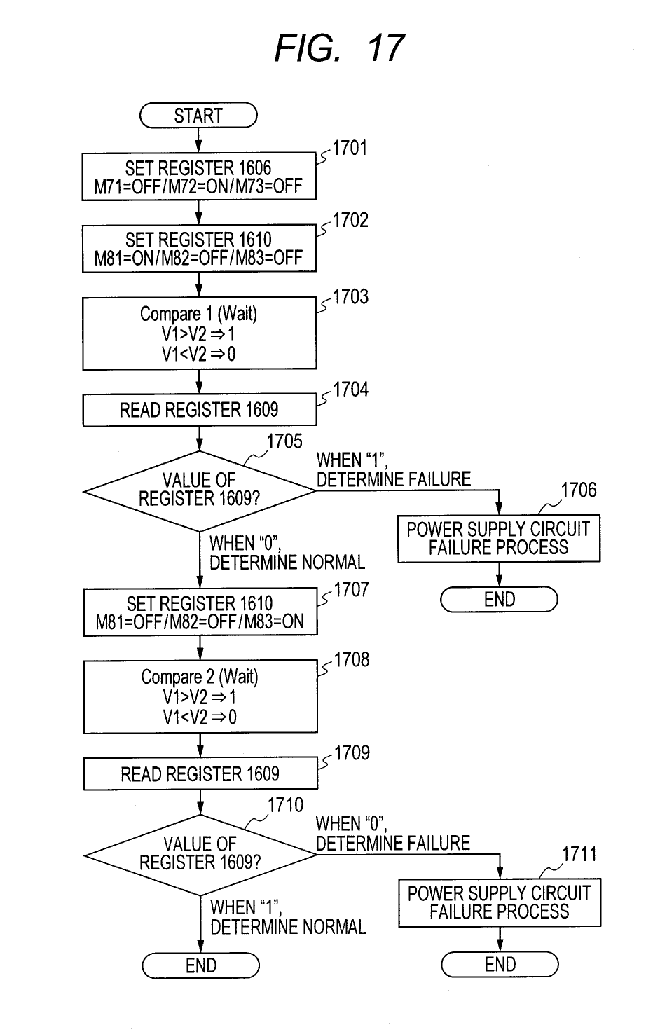

FIG. 17 shows a procedure of detecting a failure in the power supply circuit 404 illustrated in FIG. 16.

The registers 1606 and 1610 are set by control of the sequencer 105 (1701 and 1702). In the example, the register 1606 is set so that the n-channel-type MOS transistors M71 and M73 enter the off state and the n-channel-type MOS transistor M2 enters the on state, and the register 1610 is set so that the n-channel-type MOS transistor M81 enters the on state and the n-channel-type MOS transistors M82 and M83 enter the off state.

In the comparator CMP1, the output voltage V1 of the voltage decreasing circuit 1601 and the output voltage V2 of the voltage decreasing circuit 1611 are compared with each other. The comparison result is written in the register 1609 (1703). In the case where V1 is higher than V2 (V1>V2), the output of the comparator CMP1 becomes the logical value “1”. In the case where V2 is larger than V1 (V1<V2), the output of the comparator CMP1 becomes the logical value “0”.

By the control of the sequencer 105, the comparison result in the step 1703 is read from the register 1609, and the logical value of the result is determined (1704 and 1705). When the comparison result in the step 1703 is the logical value “1”, it is determined that the power supply circuit 404 fails, and a predetermined interrupt process on the failure of the power supply circuit 404 is executed by the CPU 102 (1706). When the comparison result in the step 1703 is the logical value “0”, it is determined that the power supply circuit 404 operates normally under the conditions set in the steps 1701 and 1702, and the settings in the register 1610 are changed (1707). In the example, the settings in the register 1610 are changed so that the n-channel-type MOS transistors M81 and M82 enter the off state and the n-channel-type MOS transistor M83 enters the on state.

In the comparator CMP1, the output voltage V1 of the voltage decreasing circuit 1601 and the output voltage V2 of the voltage decreasing circuit 1611 are compared, and the comparison result is written in the register 1609 (1708). In the case where V1 is higher than V2 (V1>V2), an output of the comparator CMP1 becomes the logical value “1”. In the case where V2 is higher than V1 (V1<V2), an output of the comparator CMP1 becomes the logical value “0”.

By the control of the sequencer 105, the comparison result in the step 1708 is read from the register 1609, and the logical value of the read result is determined (1709 and 1710). In the case where the comparison result in the step 1709 is the logical value “0”, it is determined that the power supply circuit 404 fails regardless of the determination in the step 1705, and a predetermined interrupt process on the failure of the power supply circuit 404 is executed (1711). In the case where the comparison result in the step 1703 is the logical value “1”, it is determined that the power supply circuit 404 operates normally, and the failure detection is finished.

In the configuration, without directly monitoring the output voltage Vdd of the analog circuit 1602, a failure in the power supply circuit 404 can be detected.

Although the setting of the register 1610 is changed in the step 1707, the setting of the register 1606 may be changed.

### Seventh Embodiment

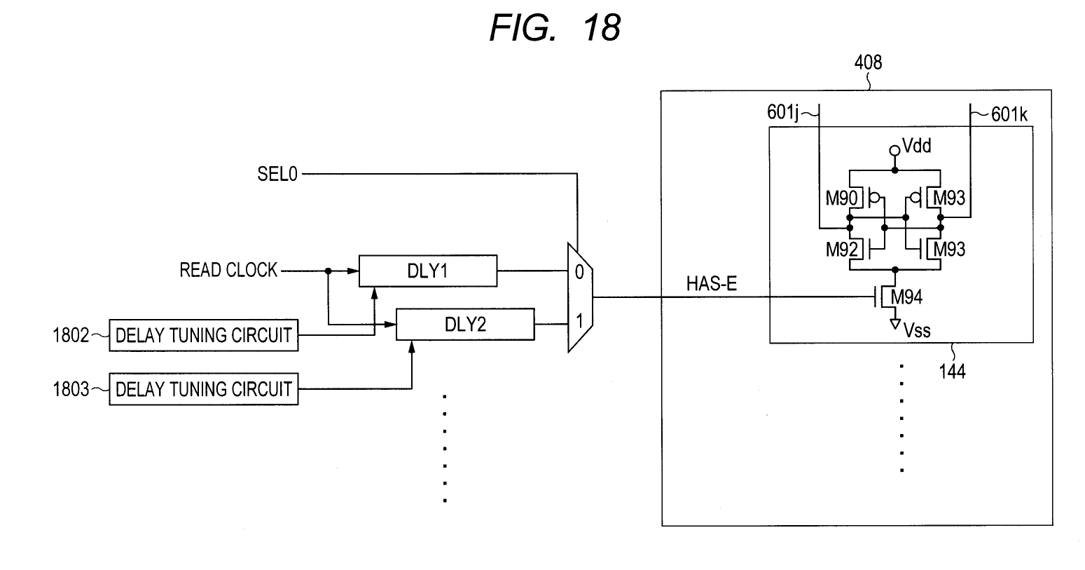

FIG. 18 shows a configuration example of the hierarchical sense amplifier circuit 144 and its periphery.

The hierarchical sense amplifier circuit 144 is obtained by coupling p-channel-type MOS transistors M90 and M91 and n-channel-type MOS transistors M92, M93, and M94. The p-channel-type MOS transistor M90 and the n-channel-type MOS transistor M92 are coupled to each other in series. The sub bit line 601j is coupled to the series connection node. The p-channel-type MOS transistor M91 and the n-channel-type MOS transistor M93 are coupled to each other in series. The sub bit line 601k is coupled to the series connection node. The sources of the p-channel-type MOS transistors M90 and M91 are coupled to the high-potential-side power source Vdd. The sources of the n-channel-type MOS transistors M92 and M93 are coupled to the low-potential-side power source Vss via the n-channel-type MOS transistor M94. An HSA enable signal HSA_E is transmitted to the gate of the n-channel-type MOS transistor M94. When the HSA enable signal HSA_E is asserted to the high level, the n-channel-type MOS transistor M94 is turned on, and the hierarchical sense amplifier circuit 144 enters an active state. The HSA enable signal HSA_E is generated by a configuration including a plurality of delay circuits DLY1 and DLY2 and a selector 1801 for selectively transmitting outputs of the delay circuits DLY1 and DLY2 to the gate of the n-channel-type MOS transistor M94. The operation of the selector 1801 is controlled by a select signal SEL0. When the select signal SEL0 has the logical value “0”, the output signal of the delay circuit DLY1 is selectively transmitted to the gate of the n-channel-type MOS transistor M94. When the select signal SEL0 has the logical value “1”, the output signal of the delay circuit DLY2 is selectively transmitted to the gate of the n-channel-type MOS transistor M94. The output of the selector 1801 becomes the HSA enable signal HSA_E. The plurality of delay circuits DLY1 and DLY2 have the function of delaying an input read clock signal by predetermined time. The delay times of the plurality of delay circuits DLY1 and DLY2 can be adjusted by delay time tuning circuits 1802 and 1803, respectively.

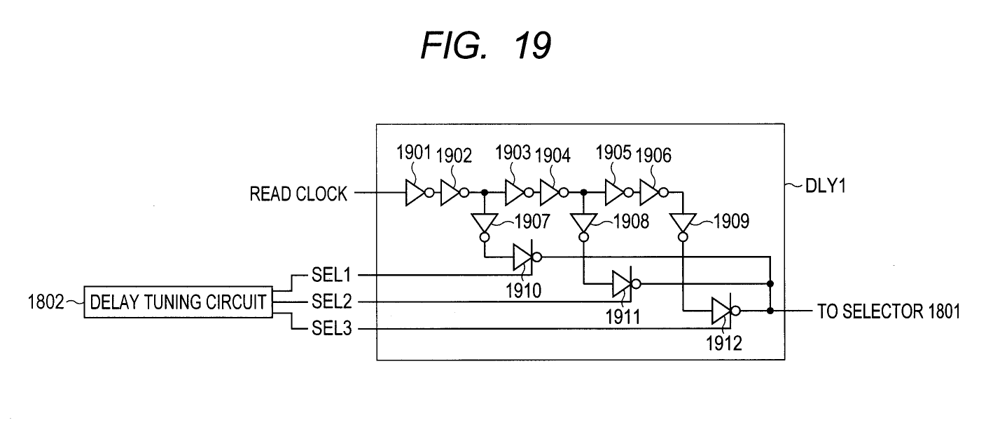

FIG. 19 shows a configuration example of the delay circuit DLY1.

The delay circuit DLY1 is obtained by coupling inverters 1901 to 1902 and tri-state buffers 1910 to 1912. The inverters 1901 to 1906 are coupled to each other in series. The series connection node of the inverters 1902 and 1903 is coupled to the input terminal of the tri-state buffer 1910 via an inverter 1907. The series connection node of the inverters 1904 and 1905 is coupled to the input terminal of the tri-state buffer 1911 via the inverter 1908. The output terminal of the inverter 1906 is coupled to the input terminal of the tri-state buffer 1912 via the inverter 1909. Outputs of the tri-state buffers 1910 to 1912 are transmitted to the selector 1801. The delay time tuning circuit 1802 outputs select signals SEL1, SEL2, and SEL3. By the select signals SEL1, SEL2, and SEL3, the states of the corresponding tri-state buffers 1910 to 1912 are controlled. By selectively asserting any of the select signals SEL1, SEL2, and SEL3, outputs of the inverters 1910, 1911, and 1912 are selectively transmitted to the selector 1801. It can adjust delay time in the delay circuit DLY1.

The delay circuit DLY2 has the same configuration as that of the delay circuit DLY1.

An output of the hierarchical sense amplifier circuit 144 is transmitted to the failure detection circuit 103 in a manner similar to the case shown in FIG. 8.

In the configuration, the consistency between the plurality of delay circuits DLY1 and DLY2 is examined as follows.

By the control of the sequencer 105, the select signal SEL0 is set to the logical value “0”. Accordingly, an output of the delay circuit DLY1 is selected by the selector 1801. By the control of the sequencer 105, settings in the delay time tuning signal circuit 1802 are made. For example, in the delay time tuning signal circuit 1802, the select signal SEL1 is set to the logical value “1”, the select signal SEL2 is set to the logical value “0”, and the select signal SEL3 is set to the logical value “0”. It makes the tri-state buffer 1910 in the delay circuit DLY1 conductive, and an output of the inverter 1907 is transmitted to the hierarchical sense amplifier circuit 144 via the tri-state buffer 1910. The hierarchical sense amplifier circuit 144 is activated at an enable timing of the HSA enable signal HSA_E, and an output (read value) of the sense amplifier circuit 144 at that time is written in the register in the failure detection circuit 103. The value will be called a read value 1_1.

Next, by the control of the sequencer 105, the settings in the delay time tuning circuit 1802 are changed. For example, in the delay time tuning circuit 1802, the select signal SEL1 is set to the logical value “0”, the select signal SEL2 is set to the logical value “1”, and the select signal SEL3 is set to the logical value “0”. It makes the tri-state buffer 1911 in the delay circuit DLY1 conductive, and an output of the inverter 1908 is transmitted to the hierarchical sense amplifier circuit 144 via the tri-state buffer 1911. The hierarchical sense amplifier circuit 144 is activated again at an enable timing of the HSA enable signal HSA_E, and an output (read value) of the sense amplifier circuit 144 at that time is written in the register in the failure detection circuit 103. The value will be called a read value 1_2.

Next, by the control of the sequencer 105, the settings in the delay time tuning circuit 1802 are changed. For example, in the delay time tuning circuit 1802, the select signal SEL1 is set to the logical value “0”, the select signal SEL2 is set to the logical value “0”, and the select signal SEL3 is set to the logical value “1”. It makes the tri-state buffer 1912 in the delay circuit DLY1 conductive, and an output of the inverter 1909 is transmitted to the hierarchical sense amplifier circuit 144 via the tri-state buffer 1912. The hierarchical sense amplifier circuit 144 is activated again at an enable timing of the HSA enable signal HSA_E, and an output (read value) of the sense amplifier circuit 144 at that time is written in the register in the failure detection circuit 103. The value will be called a read value 1_3.

Subsequently, by the control of the sequencer 105, the select signal SEL0 is set to the logical value “1”. Accordingly, an output of the delay circuit DLY2 is selected by the selector 1801.

By the control of the sequencer 105, settings in the delay time tuning signal circuit 1803 are made. For example, in the delay time tuning signal circuit 1803, the select signal SEL1 is set to the logical value “1”, the select signal SEL2 is set to the logical value “0”, and the select signal SEL3 is set to the logical value “0”. It makes the tri-state buffer 1910 in the delay circuit DLY2 conductive, and an output of the inverter 1907 is transmitted to the hierarchical sense amplifier circuit 144 via the tri-state buffer 1910. The hierarchical sense amplifier circuit 144 is activated at an enable timing of the HSA enable signal HSA_E, and an output (read value) of the sense amplifier circuit 144 at that time is written in the register in the failure detection circuit 103. The value will be called a read value 2_1.

Next, by the control of the sequencer 105, the settings in the delay time tuning circuit 1803 are changed. For example, in the delay time tuning circuit 1803, the select signal SEL1 is set to the logical value “0”, the select signal SEL2 is set to the logical value “1”, and the select signal SEL3 is set to the logical value “0”. It makes the tri-state buffer 1911 in the delay circuit DLY2 conductive, and an output of the inverter 1908 is transmitted to the hierarchical sense amplifier circuit 144 via the tri-state buffer 1911. The hierarchical sense amplifier circuit 144 is activated again at an enable timing of the HSA enable signal HSA_E, and an output (read value) of the sense amplifier circuit 144 at that time is written in the register in the failure detection circuit 103. The value will be called a read value 2_2.

Next, by the control of the sequencer 105, the settings in the delay time tuning circuit 1803 are changed. For example, in the delay time tuning circuit 1803, the select signal. SEL1 is set to the logical value “0”, the select signal SEL2 is set to the logical value “0”, and the select signal SEL3 is set to the logical value “1”. It makes the tri-state buffer 1912 in the delay circuit DLY2 conductive, and an output of the inverter 1909 is transmitted to the hierarchical sense amplifier circuit 144 via the tri-state buffer 1912. The hierarchical sense amplifier circuit 144 is activated again at an enable timing of the HSA enable signal HSA_E, and an output (read value) of the sense amplifier circuit 144 at that time is written in the register in the failure detection circuit 103. The value will be called a read value 2_3.

By the control of the sequencer 105, the read values read in the register in the failure detection circuit 103 are compared. In the comparison of the read values, in the case where the read values 1_1 and 2_1 are equal to each other, the read values 1_2 and 2_2 are equal to each other, and the read values 1_3 and 2_3 are equal to each other, the consistency of the delay circuits DLY1 and DLY2 is determined as normal. However, in the case where the read values are different from each other in the comparison of the read values, it is determined that the delay circuit DLY1 or DLY2 is defective.

With the configuration, without directly monitoring outputs of the delay circuits. DLY1 and DLY2 as analog circuits, a failure in the delay circuits DLY1 and DLY2 can be detected.

### Eighth Embodiment

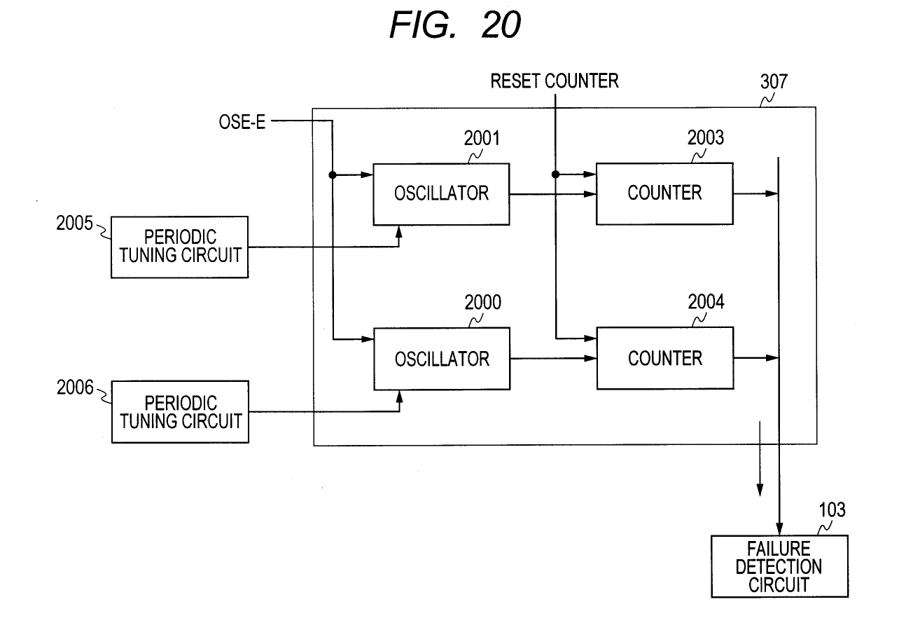

FIG. 20 shows a configuration example of the clock generator 307.

The clock generator 307 includes oscillators 2001 and 2002 for generating clock signals and counters 2003 and 2004 for counting the generated clock signals. The oscillators 2001 and 2002 have the same configuration. The counters 2003 and 2004 have the same configuration. The cycle of the clock signals output from the oscillator 2001 can be changed by a cycle tuning circuit 2005. The cycle of the clock signals output from the oscillator 2002 can be changed by a cycle tuning circuit 2006. Outputs of the counters 2003 and 2004 can be supplied to the components via the peripheral bus 309. Outputs of the counters 2003 and 2004 are also transmitted to the failure detection circuit 103.

A check to be made on the consistency between the oscillators 2001 and 2002 will now be described.

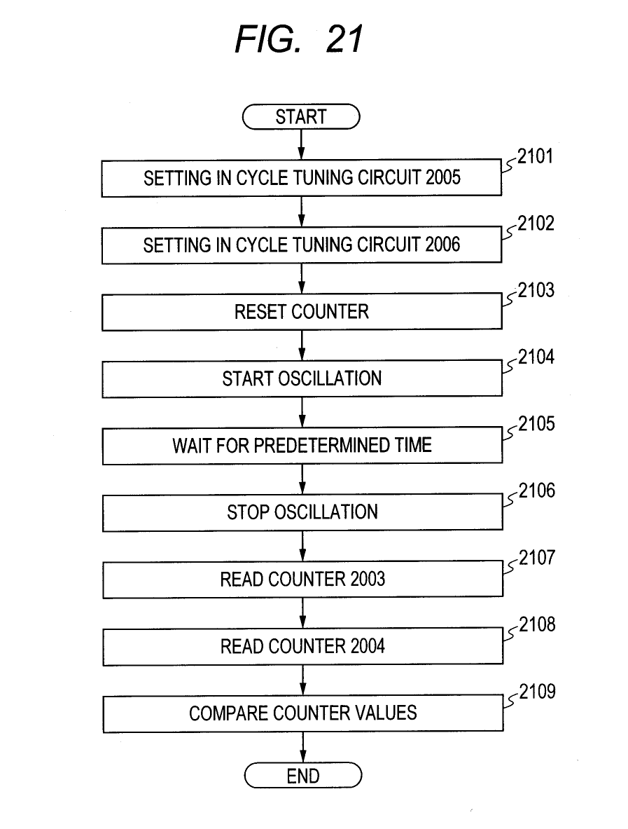

FIG. 21 shows the procedure of making a check on the consistency between the oscillators 2001 and 2002.

Settings in the cycle tuning circuits 2005 and 2006 are made by the sequencers 105 (2101 and 2102). The settings in the cycle tuning circuits 2005 and 2006 are made so that clock signals of frequencies desired to be tested are output from the oscillators 2001 and 2002.

When a counter reset signal CRST is asserted to the logical value “1” by the sequencer 105, the counters 2003 and 2004 are reset (2103).

When an oscillation enable signal OSC_E is asserted to the logical value “1” by the sequencer 105, the oscillating operations in the oscillators 2001 and 2002 are started simultaneously (2104). The state is maintained for predetermined time (wait period) (2105). During the wait period, outputs of the oscillators 2001 and 2002 are counted by the counters 2003 and 2004, respectively. After that, the oscillation enable signal OSC_E is negated to the logical value “0” by the sequencer 105, thereby simultaneously stopping the oscillating operations in the oscillators 2001 and 2002 (2106). The count value in the counter 2003 and the count value in the counter 2004 are read by the failure detection circuit 103 and compared with each other (2107, 2108, and 2109). In the comparison of the count values, in the case where the count value of the counter 2003 and the count value of the counter 2004 are equal to each other, the consistency between the oscillators 2001 and 2002 is determined normal. However, in the case where the count value of the counter 2003 and the count value of the counter 2004 are different from each other, it is determined that the oscillator 2001 or 2002 is defective.

With the configuration, a failure in the oscillators can be detected without directly monitoring the oscillation frequencies in the oscillators 2001 and 2002.

### Ninth Embodiment

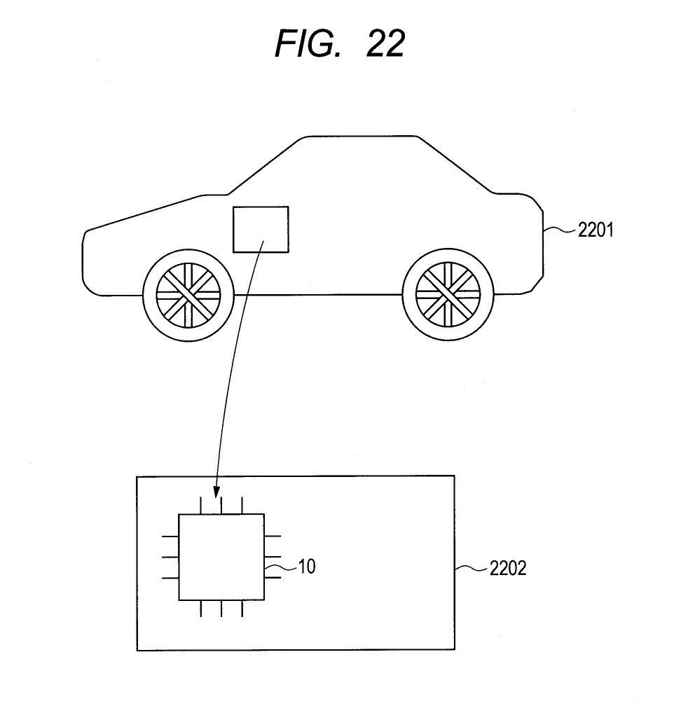

The microcomputer 10 in any of the first to eighth embodiments can be applied to various microcomputer application systems. For example, as shown in FIG. 22, the microcomputer 10 can be applied to an engine control board 2202 of a vehicle 2201. In the applied microcomputer 10, a predetermined control program generated for each microcomputer application system is executed.

The engine control board 2202 is also called an engine control unit (ECU) and controls mainly an ignition system and a fuel system in the vehicle 2201. In an automatic car, the engine control board 2202 controls the entire power train including a transmission and, in some cases, performs almost all of controls on the engine. In such an engine control board 2202, the microcomputer 10 of any of the first to eighth embodiments is mounted.

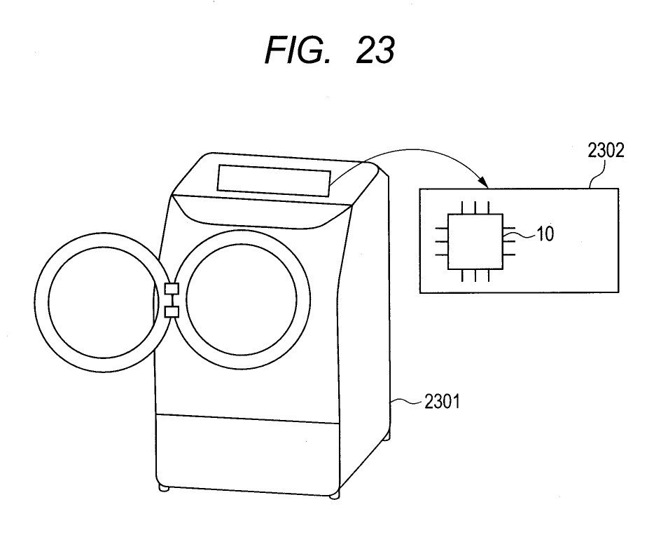

The microcomputer 10 of any of the first to eighth embodiments can be applied to a control board 2302 of a washing machine 2301 as an example of home electric appliances as shown in FIG. 23. In the control board 2302, an inverter motor mounted on the washing machine is controlled.

In the engine control board 2202 shown in FIG. 22 and the control board 2302 for home electric appliances shown in FIG. 23, failure detection on an analog part in the mounted microcomputer 10 can be automatically performed at the time of initial settings on start of the engine or at the time of power-on. The user system can be configured to indicate an error as a failure determination result to notify the end user of the failure. In this case, the end user repairs or replaces the board on which the microcomputer 10 is mounted. In the case where there is a backup system, the user system may be switched to the backup system.

Although the present invention achieved by the inventors herein has been concretely described on the basis of the embodiments, obviously, the invention is not limited to the embodiments but may be variously changed without departing from the gist.

1. A failure detecting method for a circuit to be subjected to failure detection as an object of failure detection in a semiconductor device, comprising the steps of:
changing an analog amount of the circuit to be subjected to failure detection under a predetermined condition by a tuning circuit; and
determining a state change of the circuit to be subjected to failure detection based on the change in the analog amount in the circuit to be subjected to failure detection by a failure detection circuit, thereby detecting a failure in the circuit to be subjected to failure detection.

2. The failure detecting method according to claim 1, wherein operations of the tuning circuit and the circuit to be subjected to failure detection are sequentially controlled by a sequencer under control of a central processing unit.

3. A semiconductor device including a central processing unit, comprising:
a circuit to be subjected to failure detection, as an object of failure detection;
a tuning circuit for changing an analog amount of the circuit to be subjected to failure detection under control of the central processing unit; and
a failure detection circuit for detecting a failure in the circuit to be subjected to failure detection by determining a state change of the circuit to be subjected to failure detection on the basis of a change in an analog amount in the circuit to be subjected to failure detection under control of the central processing unit.

4. The semiconductor device according to claim 3, further comprising a sequencer for sequentially controlling operations of the tuning circuit and the circuit to be subjected to failure detection under control of the central processing unit.

5. The semiconductor device according to claim 4,
wherein the circuit to be subjected to failure detection includes: a first transistor for receiving current from a first bit line for reading data in a flash memory which can be accessed by the central processing unit; and a second transistor for receiving current from a second bit line for reference corresponding to the first bit line,
wherein the tuning circuit includes: a first reference voltage generating circuit capable of changing current flowing in the first transistor separately from the second transistor; and a second reference voltage generating circuit capable of changing current flowing in the second transistor separately from the first transistor, and
wherein the failure detection circuit makes a failure determination on the first and second transistors on the basis of an output of a sense amplifier that determines a potential difference between the first and second bit lines.

6. The semiconductor device according to claim 4,
wherein the circuit to be subjected to failure detection includes: a first circuit for generating determination current of a first sense amplifier for data reading in a flash memory which can be accessed by the central processing unit; and a second circuit for generating determination current of a second sense amplifier for verification in the flash memory,
wherein the tuning circuit includes a third circuit for changing the relation between the determination current of the first sense amplifier and the determination current of the second sense amplifier under a predetermined condition, and
wherein the failure detection circuit performs failure determination on the first and second circuits by determining consistency between the determination currents in the first and second sense amplifiers on the basis of an output of the first sense amplifier or an output of the second sense amplifier.

7. The semiconductor device according to claim 4,
wherein the circuit to be subjected to failure detection includes a reference transistor for passing reference current to an input-side circuit of a verify sense amplifier in a flash memory which can be accessed by the central processing unit,
wherein the tuning circuit includes a bias voltage generating circuit capable of changing current flowing in the reference transistor, and
wherein the failure detection circuit performs failure detection on the reference transistor on the basis of an output of the verify sense amplifier.

8. The semiconductor device according to claim 4,
wherein the circuit to be subjected to failure detection includes a first analog unit for forming power source voltages for operating the components,
wherein the tuning circuit includes a first tuning circuit capable of changing an output voltage of the first power supply circuit,
the failure detection circuit includes: a second analog unit equivalent to the first power supply circuit; a second tuning circuit capable of changing output voltage of the second analog unit; and a comparator for comparing the output voltage of the first analog unit and the output voltage of the second analog unit, and
wherein the failure detection on the first analog unit is performed on the basis of an output of the comparator in the case where the output voltage of the first analog unit or the output voltage of the second analog unit is changed by the first tuning circuit or the second tuning circuit.

9. The semiconductor device according to claim 4,
wherein the circuit to be subjected to failure detection includes first and second delay circuits for forming a signal for starting a sense amplifier by delaying a clock signal,
wherein the tuning circuit includes: a first tuning circuit capable of changing delay time in the first delay circuit; and a second tuning circuit capable of changing delay time in the second delay circuit separately from the first circuit, and
wherein the failure detection circuit performs a failure determination on the first and second delay circuits by comparing an output value of the sense amplifier in the case where the delay time in the first delay circuit is changed by the first tuning circuit and an output value of the sense amplifier in the case where the delay time in the second delay circuit is changed by the second tuning circuit.

10. The semiconductor device according to claim 4,
wherein the circuit to be subjected to failure detection includes: a first oscillator which can oscillate at a predetermined frequency; and a second oscillator which can oscillate at a predetermined frequency,
the tuning circuit includes: a first periodic tuning circuit capable of tuning an oscillation period in the first oscillator; and a second periodic tuning circuit capable of tuning an oscillation period in the second oscillator separately from the first oscillator, and
wherein the failure detection circuit performs a failure determination on the first and second oscillators by comparing an output of the first oscillator in the case where the oscillation period in the first oscillator is changed by the first tuning circuit and an output of the second oscillator in the case where the oscillation period in the second oscillator is changed by the second tuning circuit.

11. A microcomputer application system in which a microcomputer executing a predetermined control program is mounted, wherein the semiconductor device according to claim 3 is applied as the microcomputer.

12. A microcomputer application system in which a microcomputer executing a predetermined control program is mounted, wherein the semiconductor device according claim 4 is applied as the microcomputer.

13. A microcomputer application system in which a microcomputer executing a predetermined control program is mounted, wherein the semiconductor device according claim 5 is applied as the microcomputer.

14. A microcomputer application system in which a microcomputer executing a predetermined control program is mounted, wherein the semiconductor device according claim 6 is applied as the microcomputer.

15. A microcomputer application system in which a microcomputer executing a predetermined control program is mounted, wherein the semiconductor device according claim 7 is applied as the microcomputer.

16. A microcomputer application system in which a microcomputer executing a predetermined control program is mounted, wherein the semiconductor device according claim 8 is applied as the microcomputer.

17. A microcomputer application system in which a microcomputer executing a predetermined control program is mounted, wherein the semiconductor device according claim 9 is applied as the microcomputer.

18. A microcomputer application system in which a microcomputer executing a predetermined control program is mounted, wherein the semiconductor device according claim 10 is applied as the microcomputer.
